(19) United States
(12) Patent Application Publication
(10) Pub. No.: US 2005/0190597 A1
(43) Pub. Date: Sep. 1, 2005

(54) Semiconductor device

(76) Inventor: Yoshihisa Kato, Otsu-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/064,499

(22) Filed: Feb. 24, 2005

(30) Foreign Application Priority Data
Feb. 27, 2004 (JP) 2004-054108
Mar. 17, 2004 (JP) 2004-076048

(51) Int. Cl. G11C 11/22

(52) U.S. Cl. 365/185.08

(57) ABSTRACT

The semiconductor device of the present invention includes a volatile latch circuit which holds data, a nonvolatile ferroelectric capacitor circuit which holds data, and a switch circuit which connects and disconnects between the latch circuit and the ferroelectric capacitor circuit.

### BACKGROUND OF THE INVENTION

(1) Field of the Invention

The present invention relates to a high-speed reconfigurable logic circuit in which ferroelectric capacitors are included.

(2) Description of the Related Art

In recent years, there has been an increase in need that “debugging to be completed until the shipping in accordance with sophistication of processing details of LSI” or that “it is wished to correct a bug found after the shipping”. Following that, a demand for an electronically reconfigurable logic circuit has been increased. There are commercialized circuits such as a Field Programmable Gate Array (FPGA) and a Programmable Logic Device (PLD).

A conventional reconfigurable logic circuit is explained with references to drawings. FIGS. 1A to 1D are diagrams showing circuit elements used in a reconfigurable logic circuit. FIG. 1A shows a configuration of a pass transistor. A conduction/non-conduction between a terminal “a” and a terminal “b” of the transistor is controlled by a Static Random Access Memory (SRAM) connected to a gate. This SRAM indicates a latch circuit which statically holds 1 bit. FIG. 1B shows a configuration of a buffer. The SRAM controls whether or not a signal entered a terminal “in” is got out from a terminal “out”. FIG. 1C shows a configuration of a multiplexer (MUX). The SRAM controls a connection between one of input terminals “in 0” and “in 1”, and an output terminal “out”. FIG. 1D shows a configuration of a look-up table (LUT). The SRAM determines data outputted from the output terminal “out” in accordance with inputs from the four input terminals “in 0” to “in 3”. As described in the above, the operations of all circuit elements are determined by a logic state of the SRAM.

The reconfigurable logic circuit is made up of these circuit elements. The circuit configuration is changed by rewriting binary data to SRAM in each circuit element. That is, the followings are changed: a connection by ON/OFF switching of the pass transistor; an output of a signal outputted from a buffer; a signal selection by switching MUX; and data processing such as a logical OR and a comparison by the LUT. The binary data stored in the SRAMs is called circuit configuration information. The circuit configuration information is stored in an external nonvolatile memory. It is taken into the reconfigurable logic circuit via a serial interface from the nonvolatile memory in the case of starting the reconfigurable logic circuit or of changing details of the data processing.

In the reconfigurable logic circuit, the logic configuration information is transferred from nonvolatile memories to SRAMs via a serial interface so that time is required for the reconfiguration.

It is suggested a method which makes a high-speed reconfiguration to a different operation possible by including a plurality of SRAMs for performing a high-speed reconfiguration, storing the circuit reconfiguration information from an external nonvolatile memory to the SRAMs at the time of start, and switching the information.

Further, it is suggested a reconfigurable logic circuit in which nonvolatile SRAMs which can nonvolatily record data stored on the SRAMs are used and store a plurality of pieces of circuit reconfiguration information (e.g. “2002 Symposium on VLSI Circuits Digest of Technical Papers”, pp. 200 to 203).

FIG. 2 is a circuit diagram showing a configuration of the conventional SRAM. The conventional SRAM forms a latch circuit by connecting two inverters configured respectively by N type transistors Qn0 and Qnx0 and P-type transistors Qp0 and Qpx0. The data line pair DL and DLx for writing circuit configuration information via access transistors Qn1 and Qnx1 controlled by a control line PRG are connected to storage nodes N and NX of the latch circuit. The storage node N or NX is connected to one of the circuit elements described in the above.

The nonvolatile SRAM having ferroelectric capacitor connected respectively to the storage node N and NX is disclosed for example in Japanese Laid-Open Patent Publication No. 11-39883).

FIG. 3 is a circuit diagram showing a configuration of the nonvolatile SRAM. One of the electrodes of the ferroelectric capacitors Cf0, Cfx0, Cf1, and Cfx1 is connected to the storage node N or NX.

Plate lines PLC0 and PLC1 are connected to the other side of the electrodes (the electrodes that are not connected to the storage nodes N and NX) of the ferroelectric capacitors. By timely driving the PLC0 and the PLC1, it is performed either a writing from the storage node N (NX) to the ferroelectric capacitors Cf0 and Cf1 (Cfx0 and Cfx1) or a writing from the ferroelectric capacitors to the storage node. The circuit configuration information is recorded as a direction of a polarization of the ferroelectric capacitors. The direction of the polarization is kept even the power is cut off. The nonvolatile SRAM can retain the circuit configuration information so that it is not necessary to take in the information at the time of start. This makes a high-speed reconfiguration possible.

For example, the Japanese Laid-Open Patent Publication No. 2000-293989, “A 512 kbit low-voltage NV-SRAM with the size of a conventional SRAM”, 2001 Symposium on VLSI Circuits Digest of Technical Papers, 2001, pp. 129-132 (hereafter referred to as reference 1), and the like suggest an ferroelectric memory device as a semiconductor memory device that is made up of ferroelectric capacitors and SRAM cell (a latch circuit).

A driving method of the conventional ferroelectric capacitor device is explained with reference to a diagram.

FIG. 4 is a circuit diagram of a nonvolatile latch circuit which is made up of a latch circuit and ferroelectric capacitors disclosed in the reference 1. The latch circuit is configured in which two inverters INV0 and INV1 are connected in cross couple, and data is written and read by the access transistors Q0 and XQ0 whose gates are controlled by a word line WL from the storage nodes N0 and XN0. The two ferroelectric capacitors CF0 and XCF0 are connected to two storage nodes N0 and XN0 of the latch circuit. The other side of the electrodes of the ferroelectric capacitors is connected to the plate line PL. In this circuit, data is stored as a direction of polarizations of the ferroelectric capacitors CF0 and XCF0 while the power is off, the data is transferred from the ferroelectric capacitors to the latch circuit when the power is turned on, and an external access in an ordinal operational state is exclusively accessed to the latch circuit.

However, a load capacitor at the time of reading data by the ferroelectric capacitor is small so that stable reading is difficult. In order to solve the problem, a circuit in which two ferroelectric capacitors are connected, to a storage node is suggested in “Ferroelectric Memory Based Secure Dynamically Programmable Gate Array”, 2002 Symposium on VLCI Circuit Digest of Technical Papers, 2002, pp. 200-203 (hereafter referred to as reference 2). FIG. 5 shows the circuit diagram.

In the circuit, two ferroelectric capacitors CF1 and XCF1 are further connected to the storage nodes N0 and XN0, and the other side of the electrodes of the ferroelectric capacitors is connected to the plate line PL1. The data of the storage node is stored as a direction of the polarization in the two pairs of ferroelectric capacitors: a pair of CF0 and CF1; and a pair of XCF0 and XCF1. The polarization direction in which the data is complementary stored. That is, the polarization direction of the paired CF0 and CF1 is opposite direction to the polarization direction of the paired XCF0 and XCF1. Further, the polarization direction of the paired CF0 and XCF0 is opposite to the polarization direction of the paired CF1 and XCF1. For example, in the case where the polarization direction of the paired CF0 and XCF0 is directed to a N0 side, the paired XCF0 and XCF1 is directed to side of the plate line. In the case where the polarization direction of the paired CF0 and CF1 is directed to the plate line side, the paired XCF0 and XCF1 is directed to the XN0 side. In order to read data stored in this way in the ferroelectric capacitors, voltage is applied between PL0 and PL1, a potential difference generated at connecting points of two pairs of serial-connected ferroelectric capacitors: a pair of CF0 and CF1; and a pair of XCF0 and XCF1, that is, at storage nodes N0 and XN0, is amplified by the latch circuit.

### SUMMARY OF THE INVENTION

However, according to the conventional technology, the first problem is that a storing capability (a retention characteristic) of the ferroelectric capacitors in the nonvolatile RAM is deteriorated by aged changes lowering a reliability of operations. Further, the second problem is that it is difficult to integrate in large scale in the case where circuit elements having nonvolatile RAMs are integrated in large scale.

Concerning the first problem, according to the nonvolatile SRAM shown in FIG. 3 and FIG. 4, a voltage of the storage node N or Nx is applied to the ferroelectric capacitors Cf0 and Cf1 or Cfx0 and Cfx1 while the device is being energized. The storing capacity (a retention characteristic) of the ferroelectric capacitors is deteriorated by polarization when a voltage is continued to be applied, causing operational malfunctions.

Explaining the first problem in other words, as shown in FIG. 5, there is a possibility that the ferroelectric built-in latch circuit to which a plurality of ferroelectric capacitors is connected to storage nodes deteriorates its capacity by a thermal history of which the data is being held depending on a state of polarization, and cause an unstable reading operation. Because it is difficult to perform stable reading operation. In the case where a complementary direction of the polarizations is written in two pairs of ferroelectric capacitors: the pair of CF0 and CF1; and the pair of XCF0 and XCF1, and further when the voltage is applied to the plate line by the reading operation, the polarization of one of the paired ferroelectrics is reversed by reading. In the case where the ferroelectrics are placed under high temperature, a phenomenon (called imprint) that the polarization hysteresis is distorted (burned) occurs. The ferroelectrics having different directions of the polarization have different distortions of the polarization hysteresis. Accordingly, the ferroelectric in which the polarization is written using a conventional method has different imprint directions before and after the reading.

Concerning the second problem, as shown in FIG. 4 and FIG. 5, the conventional ferroelectrics built-in latch circuit corresponds to a storage node of the latch circuit and connects a nonvolatile memory (formed of two or four ferroelectrics). Therefore, it has a large area of memory cell so that a high integration is difficult.

Further, concerning the second problem, the nonvolatile SRAM shown in FIG. 3 includes 6 transistors. Therefore, in the case where the integration density is increased while 6 transistors are remained to be built in each of the nonvolatile SRAMs, the area becomes large and the circuit scale becomes large by setting a plurality of nonvolatile SRAMs to all circuit elements.

Thus, the reconfigurable logic circuit having nonvolatile SRAMs using conventional ferroelectrics has problems of deterioration of performance and a difficulty of integration.

An object of the present invention is to provide a semiconductor memory device which performs stable reading operation with less deterioration in capability.

Also, another object of the present invention is to provide a semiconductor memory device which can easily improve integration density.

The semiconductor memory device which achieves the above object comprises: a volatile latch circuit which holds data; a nonvolatile ferroelectric capacitor circuit which holds data; and a switch circuit which connects and disconnects between said latch circuit and said ferroelectric capacitor circuit.

According to this structure, the connection between said ferroelectric capacitor circuit and said latch circuit can be cut off electrically by the switch circuit when the volatile latch circuit is powered. Therefore, the deterioration of characteristic of ferroelectric capacitor (retention characteristic) caused by applying voltage on the ferroelectric capacitor circuit while the latch circuit is powered can be prevented. In other words, the semiconductor memory device can perform stable reading operation with less capability deterioration.

Here, said switch circuit may connect between said latch circuit and said ferroelectric capacitor circuit only when data is transferred between said latch circuit and said ferroelectric capacitor circuit.

According to this structure, voltage is applied to the ferroelectric capacitor circuit only for a necessary minimum time period when the circuit is activated, that is, only when the configuration is performed. Therefore, the capability deterioration of the ferroelectric capacitor circuit can be restrained to the minimum.

Here, the semiconductor memory device may further comprises a logic circuit whose configuration is changeable in accordance with the data held in said latch circuit.

According to this structure, the latch circuit functions as a sense circuit which reads out data stored in the ferroelectric capacitor circuit so that it is reconfigured only by outputting data to the latch circuit from the ferroelectric capacitor circuit via the switch circuit. Therefore, the configuration at start-up of the device can be achieved in high-speed.

Here, said ferroelectric capacitor circuit may include: a first circuit having a nonvolatile ferroelectric element which holds data; and a second circuit having a nonvolatile ferroelectric element which holds data, and said switch circuit selects one of the first circuit and the second circuit, and connects between the selected circuit and said latch circuit only when data is transferred between said latch circuit and said ferroelectric capacitor circuit.

According to this structure, two types of circuit configuration information for configuring the logic circuit are held in the ferroelectric capacitor circuit. Therefore, the reconfiguration can be achieved in high-speed by switching the information types by the switch circuit.

Here, said logic circuit may be configured to be one of i) a switch transistor which is turned on depending on the data held in said latch circuit, ii) a buffer circuit whose output is controlled depending on the data held in said latch circuit, and iii) a selection circuit whose selection is controlled depending on the data held in said latch circuit.

According to this structure, the following can be dynamically configured: a connection by switching on and off of the switch transistor; an output control of a signal entered the buffer circuit; and a signal selection by the selection circuit.

Here, the semiconductor memory device may comprises a table circuit which is formed of unit circuits, wherein one of the unit circuits may include said latch circuit, said ferroelectric capacitor circuit and said switch circuit and each of the other unit circuits has a same structure as the one unit circuit, and said logic circuit may be a selection circuit which selects one of the unit circuits.

According to this structure, by holding data which define functions such as a logical OR and a comparison in the table circuit, the unit circuit can be dynamically changed as a look-up table (LUT).

Here, the semiconductor memory device may comprise circuit blocks for processing data, wherein one of said circuit blocks may include said latch circuit, said ferroelectric capacitor circuit, said switch circuit and said logic circuit, and each of the other circuit blocks may have a same structure as said one circuit block.

According to this structure, here, the semiconductor memory device may further comprise a control unit operable to control reconfiguration of a circuit configuration for each circuit block.

With this structure, a configuration of each circuit block can be independently changed.

Here, said circuit blocks may include a first circuit block and a second circuit block, and said control unit may be operable to reconfigure a circuit configuration of the second circuit block while data is processed in the first circuit block.

Here, said control unit may be operable to reconfigure a circuit configuration of said circuit blocks, each of which is separately reconfigured.

According to this structure, a configuration of a block in which the data processing is finished is independently reconfigured without stopping an operation of a block which is on data processing. Therefore, a plurality of circuit blocks can be effectively used.

Here, said circuit blocks include circuit block groups corresponding to respective stages of a pipeline processing, and said control unit may be operable to reconfigure a circuit configuration of each circuit block groups in order of the stages.

According to this structure, the peak power consumption can be reduced rather than changing the whole configuration together. Therefore, in particular, a power circuit with small driving capability such as battery can be used.

Here, said control unit may be operable to make the circuit block groups start processing of the respective stages in order of the reconfiguration.

Here, said control unit may be operable to sequentially reconfigure said circuit blocks starting from a circuit block on which processing of a stage is completed.

According to this structure, in the case where the current pipeline processing is reconfigured to a different pipeline processing, the time required for reconfiguration can be shortened.

Here, the data processing includes repetitive processing, and said control unit may be operable to reconfigure one of said circuit blocks so as to feedback to said circuit block with a processing result before a first iteration, and to reconfigure said circuit block so as not to feedback to said circuit block just before a last iteration.

According to this structure, by executing the repetitive processing in one circuit block, the circuit block can be used effectively.

Here, data may be transferred at least with two clocks from said ferroelectric capacitor circuit to said latch circuit.

According to this structure, the data is transferred at least with two clocks so that time for which the data is transferred from the ferroelectric capacitor circuit to the latch circuit is held. Therefore, the frequency of the operation clock of the logic circuit can be set higher. In addition, even in the case where the time is consumed for reading the ferroelectric capacitor circuit, the data processing can be performed without lowering the frequency of the logic circuit.

Here, the semiconductor memory device may comprise a load capacitor circuit which includes a ferroelectric capacitor that is connected to said ferroelectric capacitor circuit as a load capacitor.

Also, the semiconductor memory apparatus according to the present invention comprises: a volatile latch circuit which holds data; a nonvolatile ferroelectric capacitor circuit which holds data transferred from said latch circuit; and a load capacitor circuit which is a ferroelectric capacitor connected to said ferroelectric capacitor circuit as a load capacitor.

Here, a polarization of said load capacitor circuit may be in a direction which is not reversed in a process of reading data from said ferroelectric capacitor circuit.

According to this structure, a capacitance value of the load capacitor which changes with stored polarization is not changed before and after the reading. Therefore, the polarizations of the two load capacitors after the reading are directing to the same direction. In the other words, distortions of the polarization hysteresis of the load capacitor by the imprint become the same. Therefore, stable reading can be performed.

Here, the semiconductor memory device may comprise a driving unit operable to output a driving signal for aligning the polarization of the load capacitor circuit in one direction.

According to this structure, the driving aligns the polarization directions of the load capacitors after the reading or when the power is off. Therefore, the distortions of the polarization hysteresis of the load capacitors by the imprint become the same so that a stable reading can be performed.

Here, said driving unit may be operable to align the polarization of the load capacitor circuit in one direction which is not reversed by a reading operation.

According to this structure, the driving aligns the polarization directions of the load capacitors after the reading or when the power is off. Therefore, the distortions of the polarization hysteresis of the load capacitors by the imprint become the same so that a stable reading can be performed.

Here, the semiconductor memory device may comprise memory cells, one of which includes said latch circuit and said ferroelectric capacitor circuit and each of the other memory cells has a same structure as said one memory cell, wherein said load capacitor circuit and said memory cells may be connected to each other on a one-to-many basis.

According to this structure, the load capacitor circuit is shared by memory cells so that a cell area can be small. That is, the circuit scale is decreased so as to make high integration easy.

Here, the semiconductor memory device may comprise memory cells, one of which includes said latch circuit and said ferroelectric capacitor circuit and each of the other memory cells has a same configuration as said one memory cell, wherein said load capacitor circuit and said memory cell may be connected to each other on a one-to-one basis.

According to this structure, for example, it is appropriate in the case where the semiconductor memory device is manufactured as a memory device.

Here, said ferroelectric capacitor circuit may include a pair of ferroelectric capacitor elements, and said load capacitor circuit may include a pair of ferroelectric capacitor elements.

### FURTHER INFORMATION ABOUT TECHNICAL BACKGROUND TO THIS APPLICATION

Japanese Patent Application No. 2004-054108 filed on Feb. 27, 2004 is incorporated herein by reference, and Japanese Patent Application No. 2004-076048 filed on Mar. 17, 2004 is incorporated herein by reference.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A shows a circuit element (pass transistor) by a conventional technology.

FIG. 1B shows a circuit element (buffer) by the conventional technology.

FIG. 1C shows a circuit element (multiplexer) by the conventional technology.

FIG. 1D shows a circuit element (look up table) by the conventional technology.

FIG. 2 shows a configuration of a conventional SRAM.

FIG. 3 shows a configuration of a conventional nonvolatile SRAM.

FIG. 4 shows a ferroelectric built-in latch circuit diagram by the conventional technology.

FIG. 5 shows a ferroelectric built-in latch circuit diagram by the conventional technology.

FIG. 6A shows a circuit element function as a pass transistor in a first embodiment of the present invention.

FIG. 6B shows a circuit element function as a buffer.

FIG. 6C shows a circuit element function as a multiplexer.

FIG. 6D shows a circuit element function as a look up table.

FIG. 7 shows an example of a configuration of arithmetic elements, each of which combines circuit elements.

FIG. 8 shows a configuration of an arithmetic element array formed by arranging a plurality of arithmetic elements.

FIG. 9A shows a first example of a reconfiguration of the arithmetic element array shown in FIG. 8.

FIG. 9B is a diagram showing a timing of the reconfiguration of the arithmetic element array.

FIG. 10A shows a second example of a reconfiguration of the arithmetic element array shown in FIG. 8.

FIG. 10B is a diagram showing a timing of the reconfiguration of the arithmetic element array.

FIG. 11A shows a third example of a reconfiguration of the arithmetic array shown in FIG. 8.

FIG. 11B is a diagram showing a timing of the reconfiguration of the arithmetic element array.

FIG. 12 shows an example of a use of inefficient arithmetic element array.

FIG. 13A shows a fourth example of a reconfiguration of the arithmetic element array.

FIG. 13B shows the fourth example of the reconfiguration of the arithmetic element array.

FIG. 13C shows the fourth example of the reconfiguration of the arithmetic element array.

FIG. 14A shows a fifth example of a reconfiguration in the case where a nonvolatile memory device of a destructive read-out method is used.

FIG. 14B shows a method of a reconfiguration in the fifth example of the reconfiguration.

FIG. 15 is a circuit diagram of a pass transistor to which a plurality of nonvolatile memory cells (NVC) and SRAM that use ferroelectric capacitors are connected.

FIG. 16 shows a signal waveform at which data is read out from a ferroelectric circuit and reconfigured.

FIG. 17 shows an operation of recording circuit configuration information into a nonvolatile memory.

FIG. 18 shows a timing of an operation of polarization writing into a load capacitor.

FIG. 19 is a ferroelectric built-in latch circuit diagram in a second embodiment of the present invention.

FIG. 20 shows a driving waveform in a polling process.

FIG. 21 shows a driving waveform in a process of writing data into ferroelectrics.

FIG. 22 shows a driving waveform in a process of reading data from the ferroelectrics.

FIG. 23 shows a hysteresis indicating a state of operation.

FIG. 24 shows a hysteresis indicating a state of operation in a conventional driving.

FIG. 25 shows ferroelectric built-in latch circuit diagram in a third embodiment of the present invention.

FIG. 26 shows a driving waveform in a polling process in a fourth embodiment of the present invention.

FIG. 27A shows a conceptual configuration of a Programmable Logic Device (PLD) having ferroelectric built-in latch circuits.

FIG. 28 shows a detail of the connection circuits.

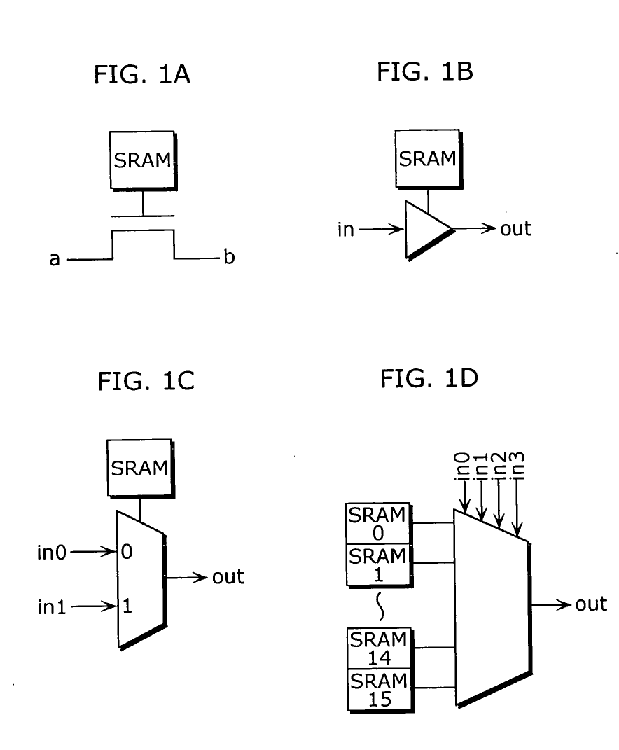

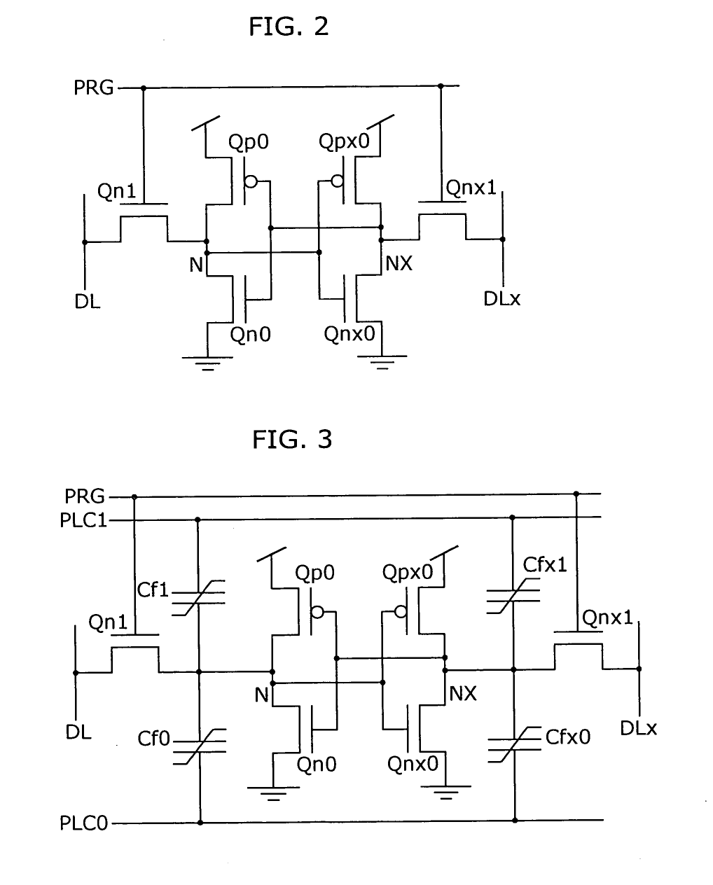

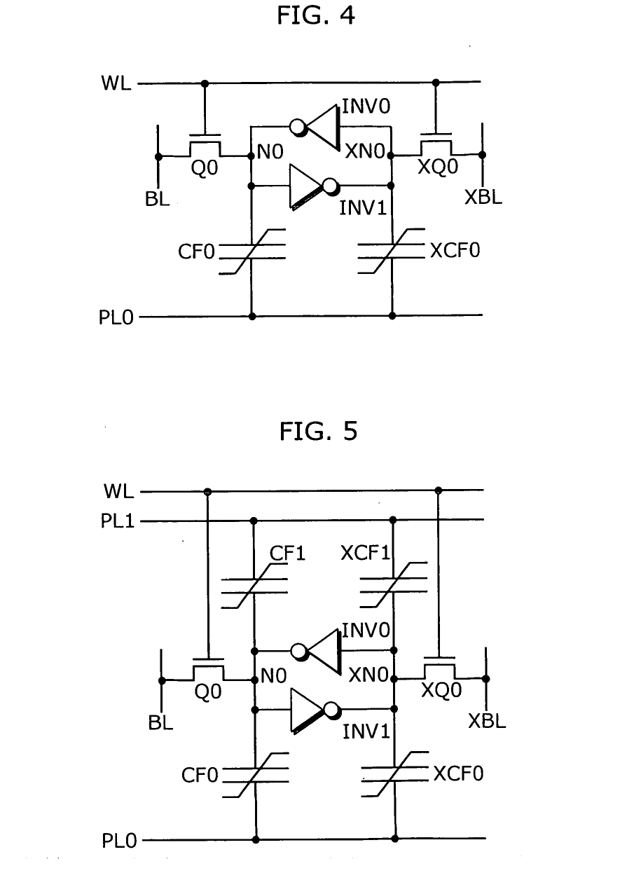

### DESCRIPTION OF THE PREFERRED EMBODIMENT(S)

### First Embodiment

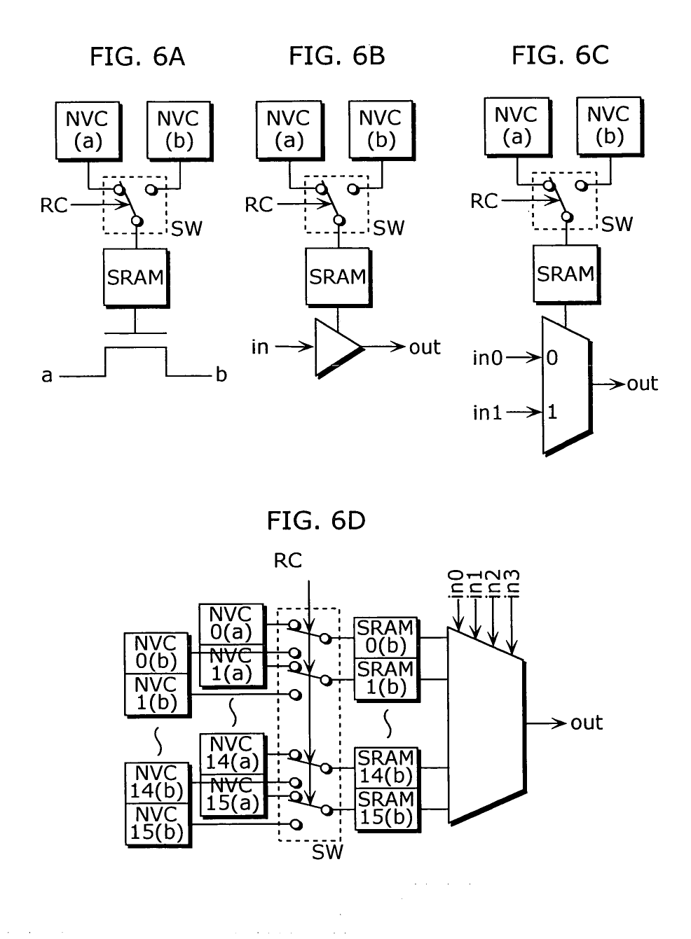

Here, a reconfigurable logic circuit in the first embodiment of the present invention is explained. FIGS. 6A to 6D are diagrams showing circuit elements used in a reconfigurable logic circuit.

FIG. 6A shows a circuit element which functions as a pass transistor. The pass transistor has nonvolatile memory cells NVC (a) and NVC (b), a switch circuit SW, a SRAM and a transistor. The NVC (a) is a nonvolatile memory cell which uses ferroelectric capacitor as a memory cell, and holds data which is a part of circuit configuration information. The NVC (b) is a similar memory cell and holds data that is a part of other circuit configuration information. The switch circuit SW selects one of the nonvolatile memory cells NVC (a) and NVC (b) in accordance with a reconfiguration control signal RC, and connects the selected nonvolatile memory cell to the SRAM only when the configuration is performed. The SRAM is a latch circuit which reads data from and writes data to the nonvolatile memory cells NVC (a) and NVC (b), via the switch SW. The transistor is controlled its connection/disconnection between a terminal “a” and a terminal “b” by the SRAM that is connected to a gate. The transistor is used for changing a connection in the logic circuit.

FIG. 6B shows a circuit element which functions as a buffer. Compared to the one in FIG. 6A, the buffer in FIG. 6B has a tri-state gate instead of the transistor. Here, the explanation about the same point is omitted and a different point is mainly explained. In the tri-state gate, data stored in the SRAM is entered an output control terminal, the data from the SRAM controls whether the signal entered a terminal “in” is got out from a terminal “out”, or outputted as high impedance.

FIG. 6C shows a circuit element which functions as a multiplexer. Compared to the one in FIG. 6A, the multiplexer in FIG. 6C has a selector instead of the transistor. Here, the explanation about the same point is omitted and a different point is mainly explained. In the selector, data stored in the SRAM is entered a selection control terminal and the data from the SRAM controls a connection between one of the input terminals “in 0” and “in 1”, and an output terminal “out”.

FIG. 6D shows a circuit element which functions as a look up table (hereafter referred to as LUT). The LUT has 16 nonvolatile memory cells NVC0 (a) to NVC15 (a), 16 nonvolatile memory cells NVC 0 (b) to NVC15 (b), 16 SRAMs, a selection switch SW, and a selection circuit having 16 inputs and one output. The nonvolatile memory cells NVC0 (a) to NVC15 (a) hold first table data of 16 bits. The nonvolatile memory cells NVC0 (b) to NVC15 (b) hold second table data of 16 bits. The selection switch SW, in accordance with a reconfiguration control signal RC, selects one set of the nonvolatile memory cells NVC0 (a) to NVC15 (a) or NVC0 (b) to NVC15 (b), and connects respectively between the selected 16 nonvolatile memory cells and 16 SRAMs only when the configuration is performed. The selection circuit having 16 inputs and one output selects one of the 16 SRAMs to the output terminal “out” in accordance with an input from four input terminal “in 0” to “in 3”. Here, the 16 SRAMs respectively stores one of the first table data and the second table data. The first and second table data indicate data processing results such as a logical OR and a comparison. The LUT can change the data processing.

As described in the above, an operation of a circuit element is determined by logical states of the SRAMs incorporated in all circuit elements. Each circuit element includes two nonvolatile memories of NVC (a) and a NVC (b), changes the switch SW controlled by the reconfiguration control signal RC, and writes the circuit configuration information recorded in one of the nonvolatile memories into a SRAM, so that it can change to a different operational state. The switch SW is connected only when data is written from the nonvolatile memory to the SRAM or when data is written from the SRAM to the nonvolatile memory, and is disconnected otherwise. Consequently, the voltage is not applied to the nonvolatile memories except when the configuration is performed so that a deterioration of characteristic of the nonvolatile memory in particular of the ferroelectric capacitor can be decreased.

In addition, the nonvolatile memory (EEPROM, ferroelectric memory (FeRAM), Magnetroresistive Random Access Memory (MRAM)) is smaller than SRAM and includes one SRAM so that it has a characteristic of small circuit area. Further, since the nonvolatile memory and the SRAM are directly connected via a switch so that a high-speed reconfiguration can be realized.

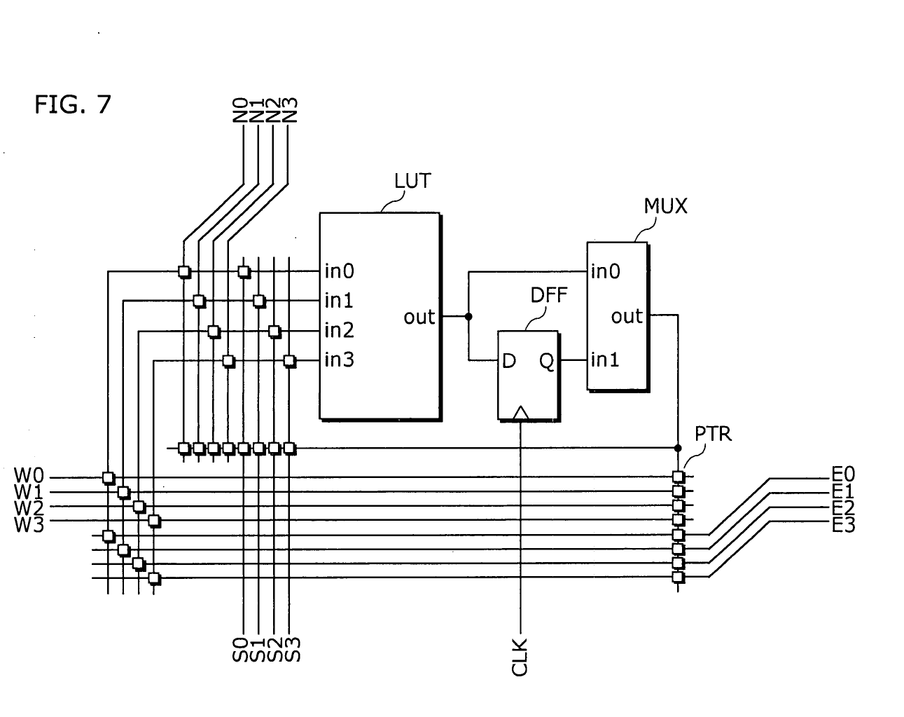

FIG. 7 shows a configuration example of an arithmetic circuit which is made up of the circuit elements. The arithmetic element shown in FIG. 7 includes a look-up table (LUT) having four inputs and one output, a D flip-flop (DFF), a multiplexer (MUX), and thirty-two pass transistors (PTR). The MUX selects one of an output of the LUT and an output from the LUT via the DFF. Each PTR is indicated as a square in FIG. 7. The terminals “a” and “b” of the PRTs are connected mutually among five wirings that are the arithmetic element and four wirings (an upper wiring, a lower wiring, right wiring and a left wiring). The PTR controls whether or not to connect these two wirings. The arithmetic element has four terminals for each direction of right, left, top and bottom. The terminals for each direction are N0 to N3, S0 to S3, W0 to W3, and E0 to E3. The four inputs of the LUT and an output of the MUX can be connected to arbitral terminals of N0 to N3, S0 to S3, W0 to W3, and E0 to E3 by thirty-two PTRs.

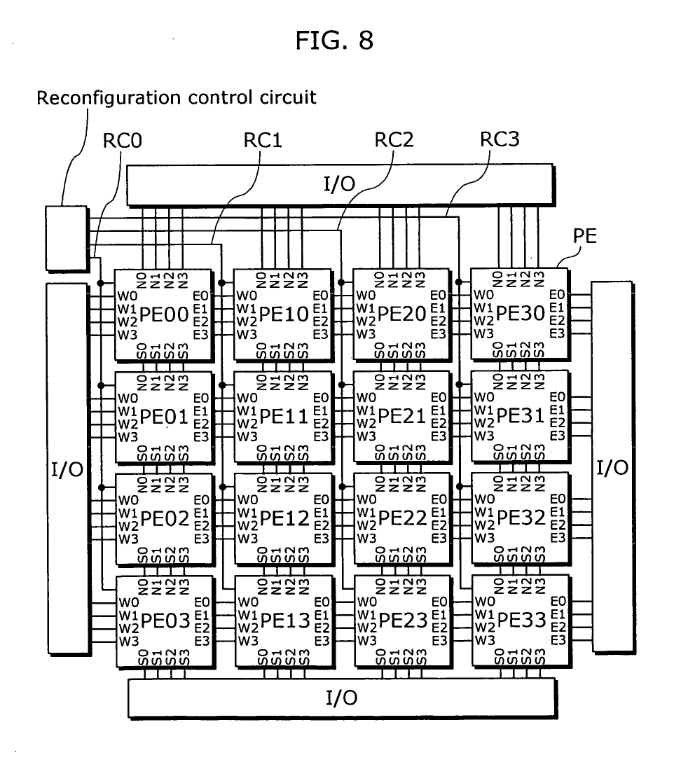

FIG. 8 is a diagram showing a configuration of the arithmetic element array formed by arranging a plurality of arithmetic elements shown in FIG. 7. The arithmetic element array includes sixteen arithmetic elements PE00 to PE33, four input/output circuit units I/O, and a reconfiguration control unit. The arithmetic elements PE00 to PE33 are arranged in a matrix. The four terminals in the four directions of each of the arithmetic elements are connected to adjacent arithmetic elements or an I/O unit. The data entered from one of the I/Os units is processed in the arithmetic element array, and is got out from one of the I/Os units. The reconfiguration control circuit outputs four reconfiguration control signals RC0 to RC3. The reconfiguration control signals RC0 to RC3 are respectively applied to columns of the arithmetic element array, and connected to a reconfiguration control signal RC that is an internal circuit element in each of the arithmetic elements which form the arithmetic element array.

That is, the following changes can be performed: a change of connection by switching on/off of the PTR; a change of data processing such as a logical OR and a comparison; and a change of a selection whether or not to output the LUT output by switching the MUX in accordance with a clock CLK.

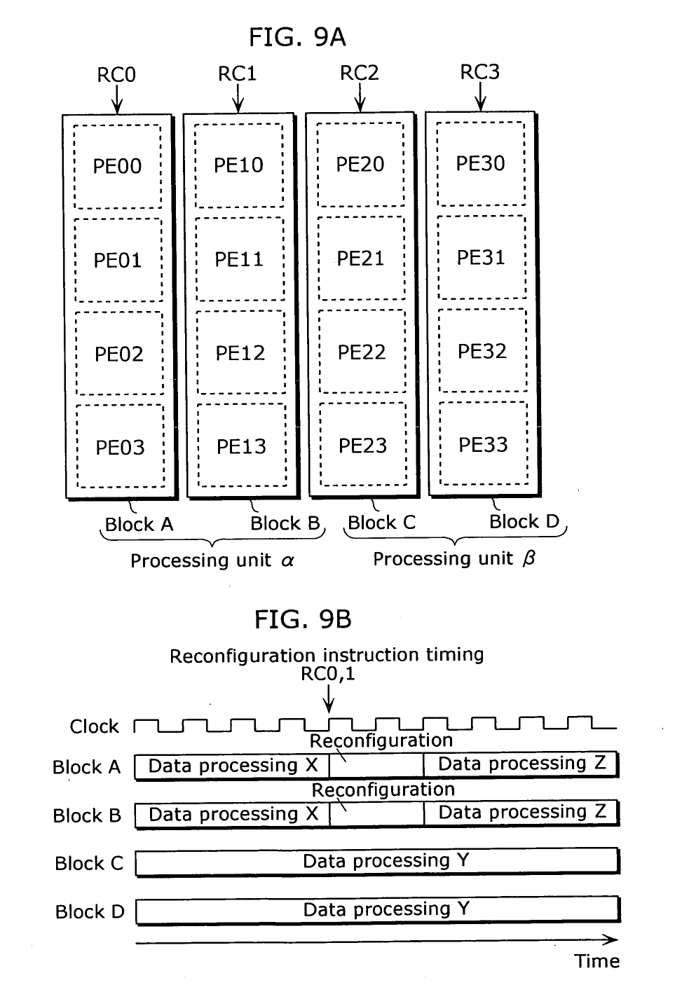

FIG. 9A shows a first reconfiguration example of the arithmetic element array shown in FIG. 8. As shown in FIG. 9A, the arithmetic element array is divided into arithmetic element groups (blocks) composed of four PEs. The reconfiguration control signals RC 0 to 3 are respectively entered a block A (PE00 to 03), a block B (PE10 to PE13), a block C (PE20 to PE23), and a block D (PE30 to PE33). It is assumed that the blocks A and B are a unit α for processing and the blocks C and D are a unit β for processing.

FIG. 9B is a diagram showing a timing of reconfiguration of the arithmetic element array shown in FIG. 9A. As shown in the diagram, it is assumed that the blocks A and B are the unit α for processing and the blocks C and D are the unit β for processing. In the unit α and β for processing, a data processing X, a data processing Y and a data processing Z are performed as shown in the diagram. That is, after finishing the data processing X in the blocks A and B, the reconfiguration control circuit changes a circuit configuration of the unit α for processing composed of the blocks A and B by outputting a reconfiguration instruction to RC0 and RC1. Consequently, a new processing Z can be started. Thus, by dividing the arithmetic element array into a plurality of units for processing and performing a different data processing in each of the units for processing, even if a data processing is being performed in one of the units for processing, another one of the units for processing in which the data processing is finished only can be reconfigured without interrupting the data processing of said one of the units for processing. Accordingly, high-speed data processing can be realized.

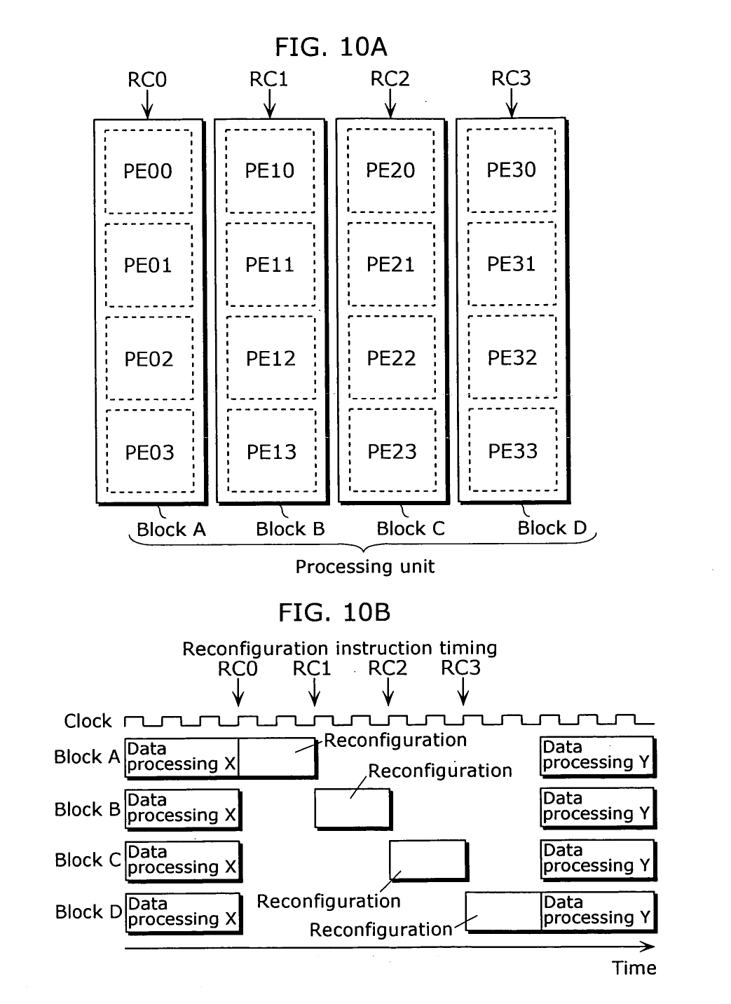

FIG. 10A shows a second reconfiguration example of the arithmetic element shown in FIG. 8. In FIG. 10A, all arithmetic elements are assumed to be as one unit for processing, and configures a circuit in order to perform data processing. Herein, the reconfiguration control circuit does not reconfigure the whole together when the data processing is finished, but reconfigures sequentially from the blocks A, B, C and D as shown in FIG. 10B. Consequently, in the case of reconfiguring the whole together, electric power to be consumed as peak power can be leveled out so that a power circuit with low electric power can be used. Accordingly, in the second reconfiguration example, a scale of the power circuit can be small.

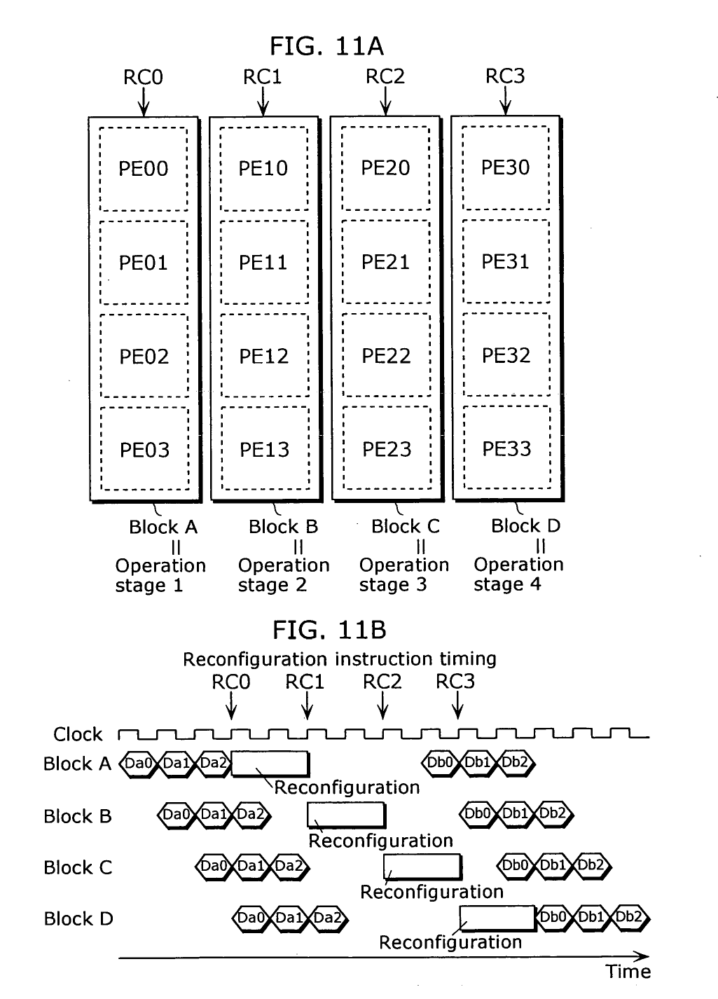

FIG. 11A shows a third reconfiguration example of the arithmetic element array shown in FIG. 8. In FIG. 11A, the blocks A to D are configured so as to respectively correspond to stages of a pipeline processing. Herein, the MUX in each arithmetic element of the blocks A to D has selected a DFF as pipeline latch. Consequently, four stages of pipeline processing composed of operation stages 1 to 4 are performed in the blocks A to D. That is, data Da0, Da1 and Da2 of stream data “a” entered from the I/O units are pipeline-processed in sequence respectively in the operation stages 1, 2, 3 and 4. In the case of reconfiguring this circuit, the reconfiguration control circuit outputs an instruction to reconfigure in order of the blocks of the operation stages in which the data processing is finished. Specifically, the block A is reconfigured by activating the reconfiguration control signal RC0 at the timing when processing of the Da2 is finished in the operation stage 1. The block B is reconfigured by activating the reconfiguration control signal RC1 at the timing when the processing of Da2 is finished in the operation stage 2 and the reconfiguration of the block A is finished. The block C is reconfigured by activating the reconfiguration control signal RC2 at the timing when the processing of the Da2 is finished in the operation stage 3 and the reconfiguration of the block B is finished. The block D is reconfigured by activating the reconfiguration control signal RC3 at the timing when the processing of the Da2 is finished in the operation stage 4 and the reconfiguration of the block C is finished. Further, before completing the reconfigurations of all blocks, stream data Db0, 1 and 2 of the new data processing b are started to be processed from the operation stage 1.

In the second reconfiguration example shown in FIG. 10B, block reconfigurations necessary for two clock periods are performed sequentially for four blocks. Therefore, eight clock periods are necessary for the reconfigurations of all blocks. In contrast, in the third reconfiguration example, the reconfigurations are sequentially performed from the block of the operation stage in which the data processing is finished while performing pipeline operation and the data processing is started in the block where the reconfiguration is finished. As the result, the length from an output from the end data Da2 of the data stream “a” to an output of a start data Db0 of the data stream “b” is shortened to five clock periods. Accordingly, the third reconfiguration example is effective for a high-speed reconfiguration and high-speed data processing of a nonvolatile memory which requires time for reading circuit configuration information. Specifically, the data processing can be performed in high-speed by assigning at least two clock cycles to access the nonvolatile memory which is driven at system clock with high frequency. On the other hand, in case that the system clock frequency is set low enough to drive the nonvolatile memory, the data processing is slow nevertheless raead out operation completes within one clock. In addition, by performing reconfiguration in accordance with a flow of data in the pipeline operation, the data processing can be performed in a block even if another block is being reconfigured so that a throughput of the data processing is improved.

Note that, in the second and third reconfiguration examples, an example of timing in which reconfigurations of respective blocks are not coincided. However, not only limited to the example, respective reconfiguration periods may be coincided. In this case, the reconfiguration time can be further shortened.

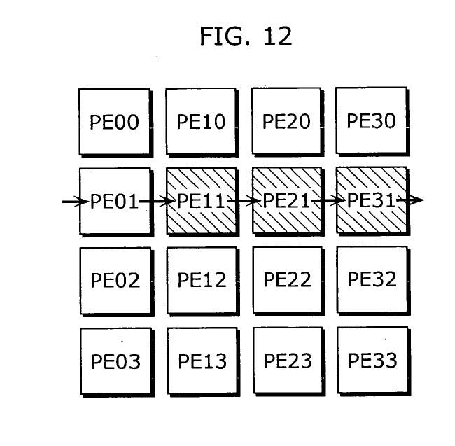

The fourth reconfiguration example shows an example of realizing the reconfiguration with fewer circuits in the case where there are circuits repeatedly used in the data processing. First, FIG. 12 shows an example of an inefficient use of the arithmetic element array. In this example, data is processed through the arithmetic elements PE01, PE11, PE21 and PE31. The same processing is performed in PE11, PE21 and PE 31 where indicated as shaded area. In the fourth reconfiguration example, the number of arithmetic elements used for this data processing can be reduced.

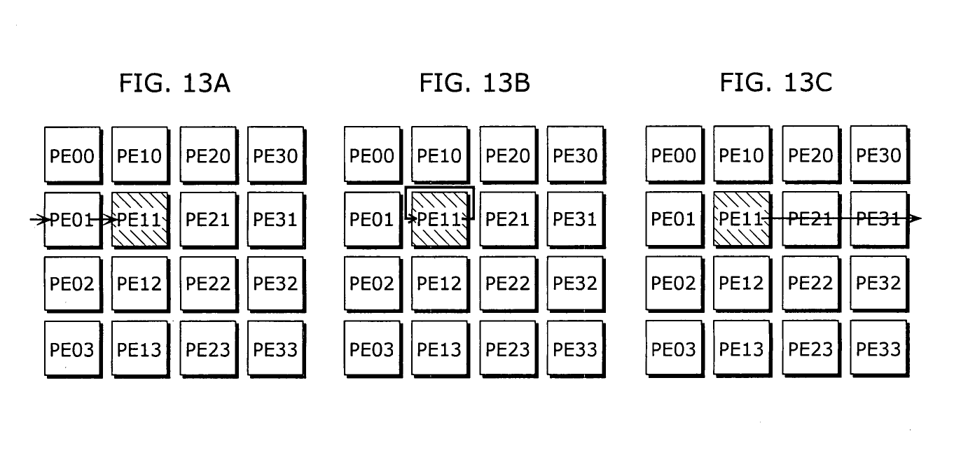

FIGS. 13A to 13C are the explanatory drawings. First, as shown in FIG. 13A, the reconfiguration control circuit controls the pass transistors to be wired so as to lead the input data from PE01 to PE11. With this circuit configuration, the data processing is performed in PE01 and PE11. Next, the circuit is reconfigured as shown in FIG. 13B. That is, a feedback loop in which the output data from the PE11 is reentered PE11 is formed. In the circuit configuration, the PE11 performs the data processing twice by sending data twice on the loop. Lastly, the circuit is reconfigured as shown in FIG. 13C, the output data from the PE11 is outputted to the outside. As described in the above, the use of reconfiguration can reduce the number of arithmetic elements used for the data processing from 44 to 2. Accordingly, it is possible to reduce the number of arithmetic elements used in the iteration processing. For example, it is applicable to processing of replacing data for a plurality of times in a cryptographic processing.

The fourth reconfiguration example is effective in the case where same data processing is performed more than once as the feedback loop. However, it is applicable to the data processing in which same data processing is not repeated. The number of arithmetic element arrays can be reduced even in a different data processing by forming a feedback loop using internal wiring, shifting the MUX to the DFF side, and rewriting the LUT every time when the data processing is performed. However, as the number of reconfigurations increase, the throughput of the data processing is slightly lowered.

Note that, by combining the third reconfiguration example and the fourth reconfiguration example, a high-speed reconfigurable logic circuit with small circuit scale can be realized.

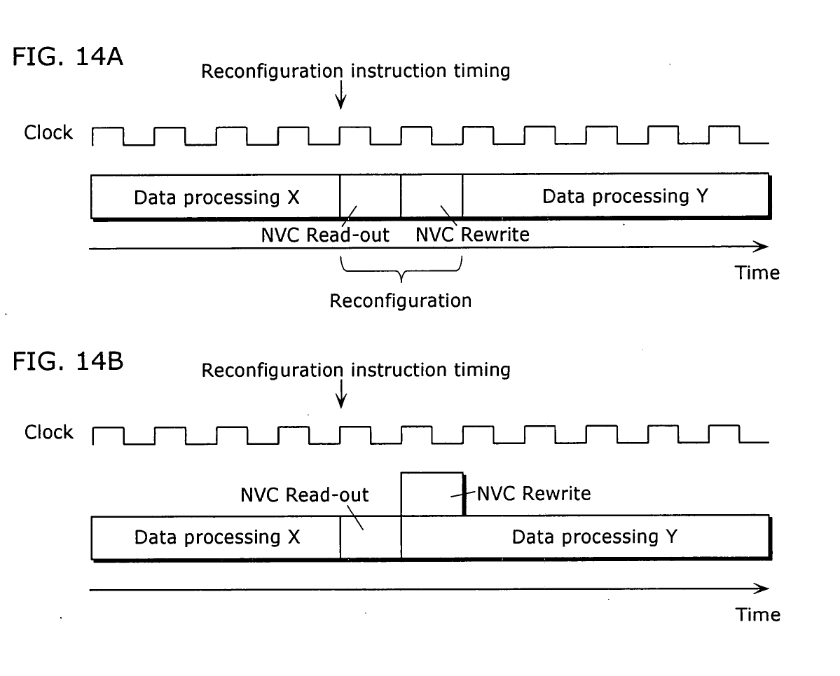

FIG. 14A is an explanatory drawing as the fifth reconfiguration example, showing a high-speed reconfiguration in the case where the nonvolatile memory device by the destructive read-out method is used. As shown in FIG. 14A, the reconfiguration operation includes an operation of reading the circuit configuration information from the nonvolatile memory NVC and storing into the SRAMs and an operation of rewriting the data into the NVC. The logic circuit becomes operable at a stage where the circuit configuration information is read out from the NVC and stored into the SRAMs. Therefore, as shown in FIG. 14B, new data processing is started at this timing. At the same time, the rewriting of data into the NVC is executed in the background. Thus, in the fifth reconfiguration example, the reconfiguration of the destructive nonvolatile memory can be realized in high-speed.

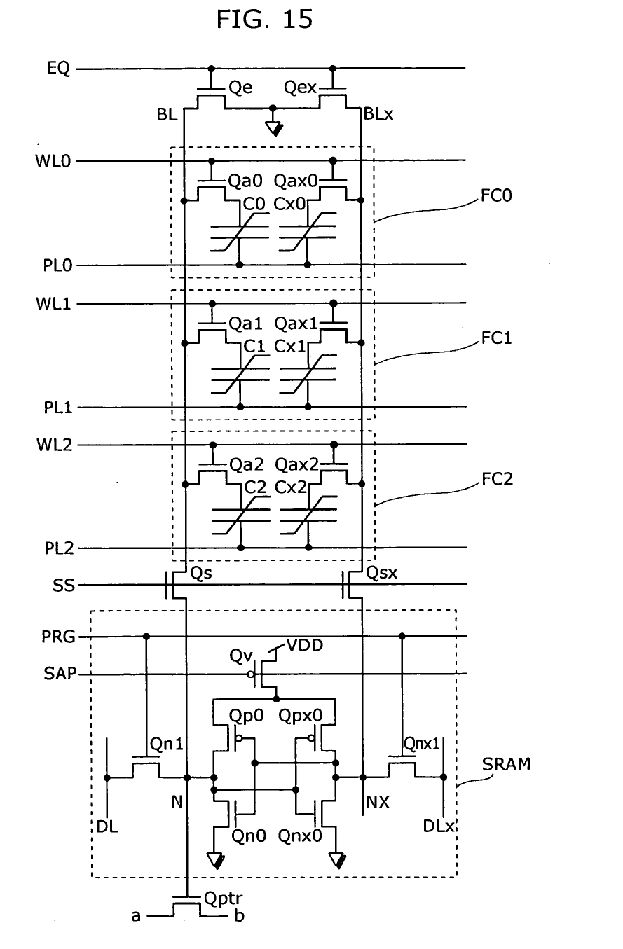

FIG. 15 shows an example of a circuit in the case where ferroelectric capacitors are used as NVC. The circuit shown in FIG. 15 corresponds to the pass transistor shown in FIG. 6A. The pass transistor includes a transistor Qptr for pass, a SRAM, ferroelectric circuits (nonvolatile memory cells) FC0 to FC2, transistors Qe and Qex, and transistors Qs and Qsx. Among the nonvolatile memory cells FC0 to FC2, FC1 and FC2 are used for recording circuit configuration information and FC0 is used as a load element for a reading operation.

The SRAM has N-type transistors Qn0 and Qnx0, P-type transistors Qp0 and Qpx0, transistors Qn1 and Qnx1, and a power control transistor Qv. The N-type transistors Qn0 and Qnx0 and the P-type transistors Qp0 and Qpx0 form two cross-couple connected inverters, that is, a latch circuit. The transistors Qn1 and Qnx1 are transistors for writing part of circuit configuration information from the data line pair DL and DLx into the ferroelectric circuits FC0 and FC1 by controlling the control line PRG. The gate of the power control transistor Qv is controlled by the control line SAP, then is connected in between the power VDD, the transistors Qp0 and Qpx0, and controls power supply to the latch circuit.

Further, the storage nodes N and NX are connected to the data line pair DL and DLx for writing the circuit configuration information via the transistors Qn1 and Qnx1 onto the control line PRG by a control, and connected to the gate of the pass transistor Qptr for controlling connection/disconnection between the terminal “a” and the terminal “b”. Furthermore, the nonvolatile memory cells FC0 to FC2 are connected to the storage nodes N or NX via the connection transistors Qs and Qsx whose gates are controlled by the control line SS.

The nonvolatile memory cells are respectively formed of one pair of two access transistors: Qa0 and Qax0; Qa1 and Qax1; and Qa2 and Qax2, and one pair of two ferroelectric capacitors: C0 and Cx0; C1 and Cx1; and C2 and Cx2. Each of the nonvolatile memory cells is connected with the bit line pairs BL and BLx. Ends of the BL and BLx are grounded via equalize transistors Qe and Qex whose gates are controlled by the control line EQ. The gates of the access transistors are controlled by word lines WL0 to WL2 and one side of electrodes of each of ferroelectric capacitors is respectively connected to one of plate lines PL0 to PL2. The FC1 and FC2 are used for recording the circuit configuration information and the FC0 is used for a load element for a reading operation.

In the first reconfiguration example, a reconfiguration is performed by issuing a reconfiguration instruction to the reconfiguration control signal RC from the reconfiguration control circuit. However, the present reconfiguration example differs with the first example in a part concerning the reconfiguration control signal. Other than that, similar operations as in the first to fourth reconfiguration examples are performed. Therefore, the same explanations are omitted.

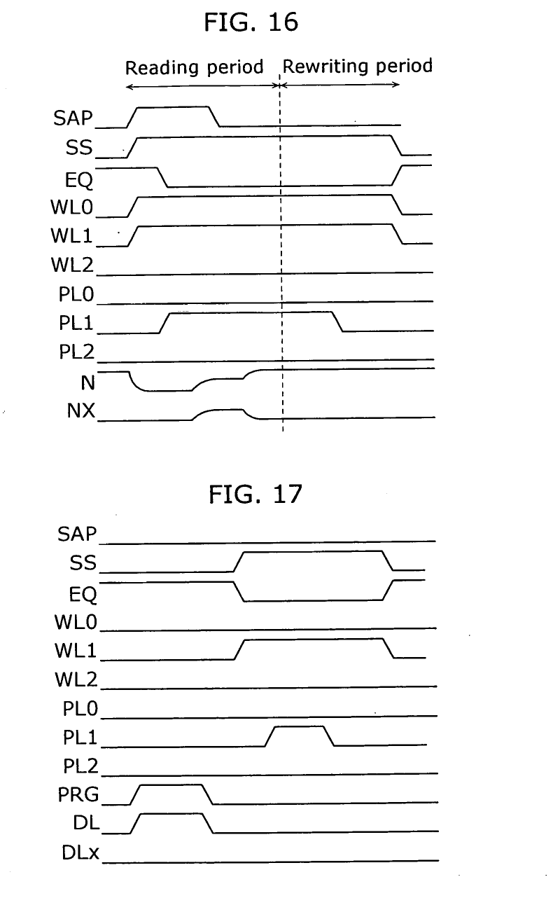

In place of the reconfiguration control signal RC, in the present embodiment, the control signals SAP, SS, EQ, WL0 to WL2, PL0 to PL2 are used. In the case of performing reconfiguration, the reconfiguration control circuit outputs the SAP, the SS, the EQ, the WL0 to WL2, and the PL0 to PL2 at the timings that are explained hereafter. FIG. 16 shows signal waveforms in which the data stored in FC1 is read out and the reconfiguration is performed. In the present embodiment, the latch circuit that is cross-coupled two inverters in the SRAM is used as amplifier circuit of signals read out from the ferroelectric capacitors.

First, the latch circuit is inactivated when the SAP turns to a high level, and the ferroelectric capacitors C0, C1, Cx0 and Cx1, a bit line pair BL and BLx, and storage nodes N and NX are grounded when the SS, the WL0 and the WL1 turns to the high level. Next, they are cut off from ground potentials when the EQ turns to a low level. The plate line PL1 is then changed to the high level. Herein, potentials distributed to the ferroelectric capacitors C0 and Cx0 are generated in the bit line BL and the storage node N. Also, potentials distributed to the ferroelectric capacitors Cx0 and Cx1 are generated in the BLx and the NX. By the way, the ferroelectric capacitor value differs depending on a direction of a polarization recorded. The capacitance value becomes small when the direction of the polarization is same as the direction of applying read voltage. It becomes large when the direction of the polarization is a reverse direction. Here, the PL0 is grounded and the read voltage is applied to the PL1 so that the capacitance values of C0 and Cx0 become large when the polarization direction is upward in FIG. 15, and becomes small when the polarization direction is downward. Also, the capacitance values of the C1 and Cx1 become small when the polarization direction is upward, and become large when the polarization direction is downward. The downward polarizations are previously recorded in the C0 and Cx0 that are load capacitors. The complementary directions of polarizations are recorded in C1 and Cx1 that record data. For example, in the case where the downward polarization is recorded in C1 and the upward polarization is recorded in Cx1, slightly higher potentials are generated through capacitance distribution for the BL and the N comparing to the BLx and NX. Herein, by supplying power to the inverters connected in cross-couple when the SAP turns to the low level, the minute potential difference is amplified to the power voltage level. Then, the storage nodes N and NX are respectively held at the high level and the low level. This operation corresponds to an operation from reading the circuit structure information from the ferroelectric capacitors and until storing the information into the SRAMs.

Next, rewriting operation is explained. The polarization which indicates a large capacitance value in the case of reading data from the ferroelectric capacitor needs to rewrite the data due to the destructive read-out causing a reversal of the polarization direction by the reading operation. This operation is simply achieved by writing the potentials stored in the storage nodes N and NX of the SRAM unit by pulsing the plate line PL1. In FIG. 16, the PL1 which has kept at the high level after the reading operation is set at the low level. Since the storage node N is at the high level, the downward polarization is written in the C1. Lastly, the SS, the WL0, the WL1 are turned to the high level and the EQ is turned to the low level. Then, the rewriting operation is completed.

With reference to FIG. 17, it is explained about an operation of recording the circuit configuration information into the nonvolatile memories. A pulse is applied to the PRG and the circuit configuration information that is a complementary signal is stored from the data line pair DL and DLx into the SRAM unit. Next, by setting the SS at the high level and the EQ at the low level, the bit line pair BL and BLx and the SRAM unit is connected and the word line of a memory cell to be written is set at the high level. In FIG. 17, the FC1 is a target to be written. In this state, the circuit configuration information is written as a polarization direction by applying a voltage pulse to the plate line PLY of the memory cell. Lastly, the SS and the WL1 are set back to the low level and the EQ at the high level. The ferroelectric capacitor is a nonvolatile memory which can preserve data without power serving. Therefore, once the circuit configuration information is written, it is not necessary to be performed again for every time when the semiconductor chip is started. Accordingly, a start-up time can be shortened.

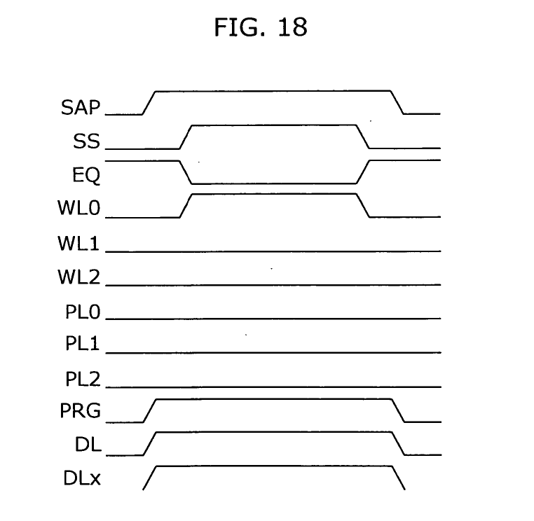

Then, in the reading operation, the downward polarization is previously recorded in the ferroelectric capacitors C0 and Cx0 which belong to the memory cell FC0 that is to be a load capacitor. With reference to FIG. 18, the writing operation is explained. The SAP is set at the high level and the inverters are inactivated in the SRAM. At the same time, the PRG, the DL and the DLx are set at the high level. In this state, when the SS and the WL0 are set at the high level and the EQ at the low level, the downward voltage is applied to the C0 and Cx0 in FIG. 15 so that the polarization direction becomes downward. After that, the SS, the EQ and the WL0 are held back to the original potentials. Further the SAP, the PRG, the DL and the DLx are set back to the original potentials and the operation is completed. As in the present embodiment, by setting two load capacitors in a direction in which the polarization is not reversed by the reading operation (downward polarization in this example), the operation of rewriting into the load capacitors after the reading can be omitted. Accordingly, this operation needs to be performed only once before the product is shipped. Also, since two load capacitors are in the same polarization direction, a problem of unstable operation concerning a bias of the polarization hysteresis (called as imprint) generated when the ferroelectric capacitors are kept in high-temperature can be restrained.

In the present embodiment, in a state where the SRAM unit is active, that is, while the logic circuit is performing data processing, a low level is applied to the SS so as to turn off the connection transistors Qs and Qsx, and the nonvolatile memory unit and the SRAM unit are separated. Further, a high level is applied to the EQ so as to turn on the equalize transistors, and the bit line pair BL and BLx are grounded. Consequently, the followings can be avoided: that a high level potential held by one of the storage nodes N and NX is leaked so that a DC potential is applied to the bit line pair; and further that the access transistors are leaked so that the DC potential is applied to the ferroelectric capacitors. Therefore, zero can be obtained between electrodes of the ferroelectric capacitors. Accordingly, a Time Dependent Dielectric Breakdown (TDDB) deterioration of the ferroelectrics can be restrained.

As described in the above, according to the present embodiment, the SRAM is used for a latch which holds configuration information of a reconfigurable logic circuit and a sense amplifier which calls data from the ferroelectric capacitors. Therefore, the circuit scale can be small.

Note that, in order to remove influences given to a characteristic by a dispersion of forming the ferroelectric capacitor elements, it is desired to place same shaped ferroelectric capacitors in up, down, right and left directions adjacent to a ferroelectric capacitor which holds the circuit configuration information. Specifically, the ferroelectric capacitors in the arithmetic element are placed in two dimensional matrix and dummy ferroelectric capacitors are placed around them. Or, the ferroelectric capacitors are placed in one-dimensional line and the dummy ferroelectric capacitors are placed around them. In the case where the circuit area becomes large, certain effects are recognized even if placing same shaped ferroelectric capacitors in the four directions adjacent to the ferroelectric capacitors. The same thing is applied to the SRAM which becomes a sense amplifier so that it is desired to place same shaped SRAMs in the four directions adjacent to the SRAMs. In the case where it is not efficient due to the placement of the circuit, the same shaped SRAMs may be placed in up and down directions or right and left directions adjacent to the SRAMs.

### Second Embodiment

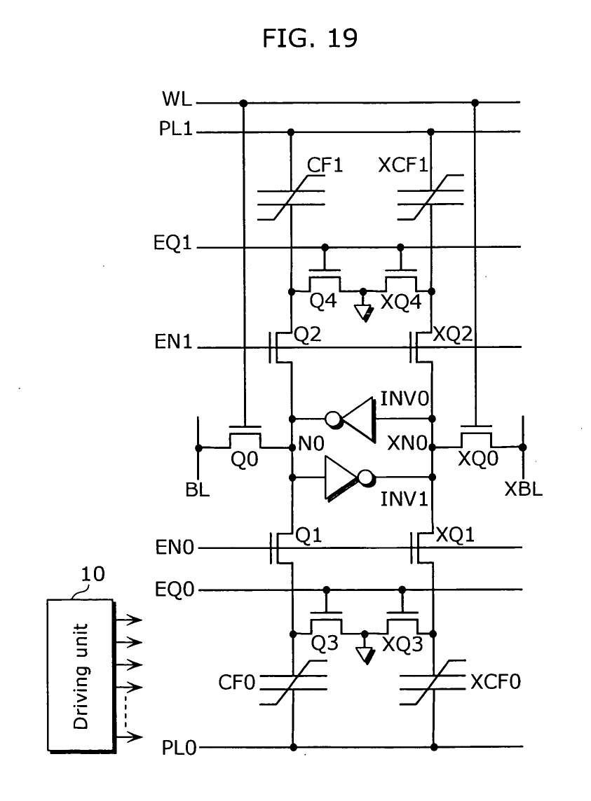

It is explained about a ferroelectric incorporated latch circuit according to the second embodiment of the present invention. FIG. 19 shows a circuit diagram of the second embodiment. In the latch circuit, two inverters INV0 and INV1 are connected in cross-couple, and data is written and read from bit lines BL and XBL by access transistors Q0 and XQ0 whose gates are controlled by the world line WL. Also, two data storage ferroelectric capacitors CF0 and XCF0 and two load ferroelectric capacitors CF1 and XCF1 are respectively connected to the two storage nodes N0 and XN0 in the latch circuit via the transistors Q1, XQ1, Q2 and XQ2 whose gates are controlled by the control lines EN0 and EN1. Theses connection nodes are available for grounding by the transistors Q3, XQ3, Q4 and XQ4 whose gates are controlled by the control lines EQ0 and EQ1. One side of electrodes of the CF0 and XCF0 is respectively connected to the plate line PL0 and one side of electrodes of the CF1 and XCF1 is respectively connected to the plate line PL1.

In such ferroelectric built-in latch circuit, in an ordinary operational state, the EN0 and EN1 and the EQ0 and EQ1 are respectively set to low potential and at high potential. It is controlled by on and off of the WL, and operates as a latch circuit which transmits complementary data to the BL and XBL. By setting the EN0 and the EN1 at low potential, the transistors Q1, XQ1, Q2 and XQ2 are turned off in order to hide the ferroelectric capacitors having large capacitance from the storage nodes so that high-speed characteristic as a latch circuit is maintained. Further, by setting the EQ0 and the EQ1 at high potential, the transistors Q3, XQ3, Q4 and XQ4 are turned on and one side of the ferroelectric capacitors is ground. Also, by setting the PL0 and the PL1 to which the other side of the electrodes is connected at the low potential, the voltage applied to the ferroelectric memories is set to zero. Consequently, a dielectric breakdown relating to a Time Dependent Dielectric Breakdown (TDDB) of a ferroelectric and a reliability problem such as imprint can be resolved.

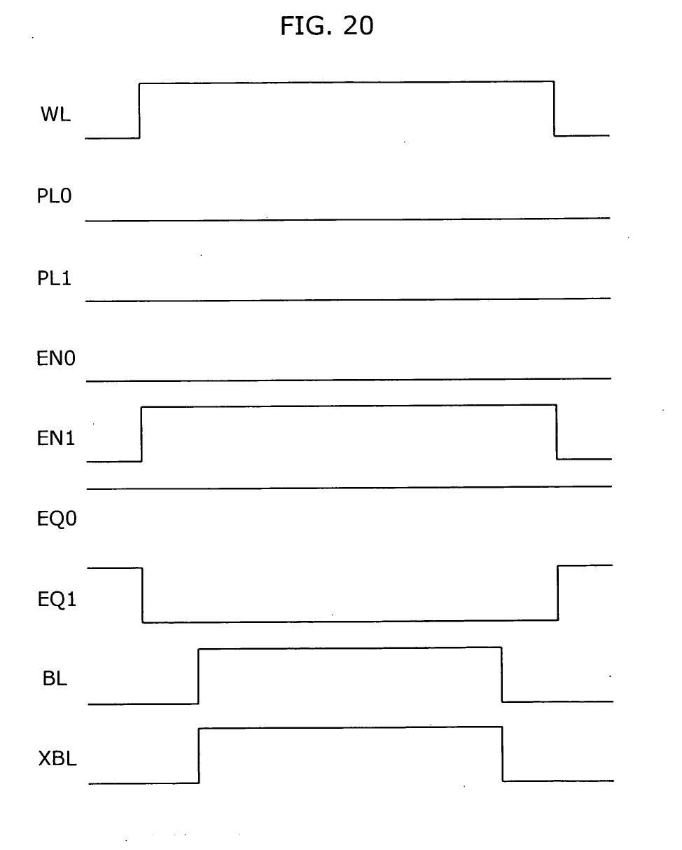

A driving unit 10 executes polling process of applying driving waveforms shown in FIG. 20 in order to set the polarization direction of the load ferroelectric capacitors CF1 and XCF1 in an upward direction shown in FIG. 19 (it is a direction in which the polarization is not reversed in data reading process from the data storage ferroelectric capacitors that are explained later). The polling processing is performed before the shipping of the ferroelectric built-in latch circuit. Since the polarization is not reversed in the reading process, it is not necessary to execute the polling process after the shipping. However, it is assumed that the polarization is lowered because of a long-term storage so that the polling process may be performed at a correct time such as before the reading operation or before turning off the power. In the polling process, as shown in FIG. 20, a positive pulse is applied to the WL and the EN1 so as to turn on the transistors Q0, XQ0, Q2 and XQ2, and connect the ferroelectric capacitors CF1 and XCF1 to the bit lines BL and XBL. Also, a negative voltage is applied to the EQ1 so as to turn off the transistors Q4 and XQ4. Next, while keeping the plate line PL1 at the low potential, a positive voltage pulse is applied to the bit lines BL and XBL. Herein, the CF1 and XCF1, a voltage enough to reverse the polarization of the ferroelectric capacitors is applied to the CF1 and XCF1 so that the polarization direction becomes upward.

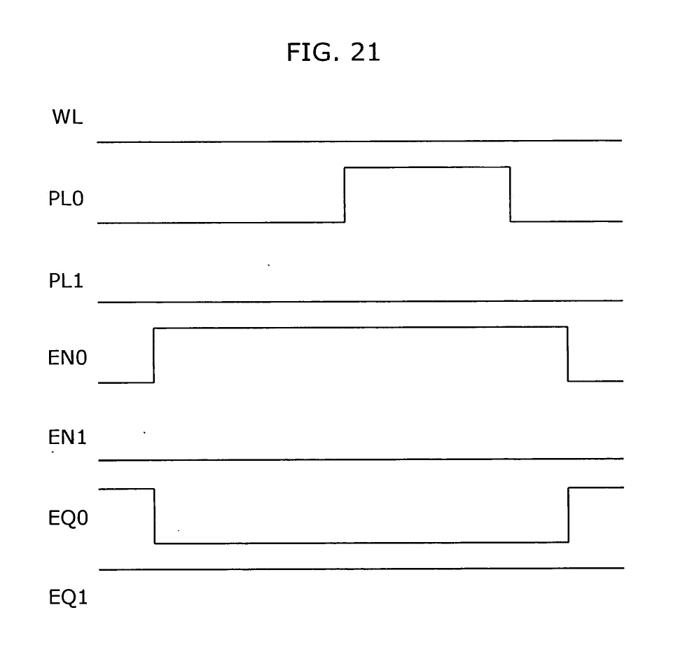

While the ferroelectric built-in latch circuit in an ordinary state operates as a latch circuit, states of complementary potentials of the storage nodes N0 and XN0 of the latch circuit are stored as polarization directions of the data storage ferroelectric capacitors CF0 and XCF0 when the power is turned off. The data writing operation into the ferroelectric can be realized by applying the driving waveforms shown in FIG. 21. First, by applying a positive voltage to the EN0, the transistors Q1 and XQ1 are turned on, and the data storage ferroelectric capacitors CF0 and XCF0 are respectively connected to the storage nodes N0 and XN0 of the latch circuit. Also, a negative voltage is applied to the EQ0 and the transistors Q3 and XQ3 are turned off. Herein, a polarization of the data storage ferroelectric capacitors connected to the storage nodes that are high potentials becomes downward shown in FIG. 19. Next, by applying a positive voltage pulse to the plate line PL0, a polarization of the data storage ferroelectric capacitors connected to the storage nodes that are low potentials becomes upward. After the operation of writing data into the ferroelectrics is completed, the power is turned off.

In summary, the polarizations are as follows: the load ferroelectric capacitors CF1 and XCF1 are upward by the polling process; and the data storage ferroelectric capacitors CF0 and XCF0 respectively becomes upward and downward when the storage nodes N0 and XN0 are respectively low potential and high potential by the data writing process, and respectively becomes downward and upward when the storage nodes N0 and XN0 are respectively high potential and low potential.

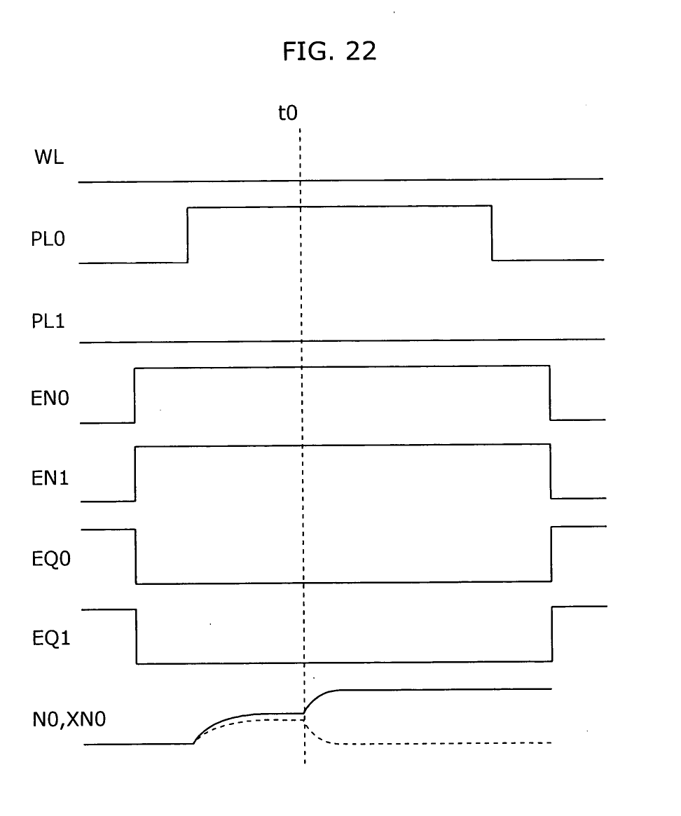

At the time when the ferroelectric built-in latch circuit is started, the data stored in the data storage ferroelectric capacitors CF0 and XCF0 as polarization directions are restored to the latch circuit as complementary potentials of the storage nodes N0 and XN0 of the latch circuit. The operation of reading data from the ferroelectrics can be realized by applying the driving waveforms shown in FIG. 22. First, in a state where the power (not shown in FIG. 19) of the inverters INV0 and INV1 are turned off, by applying a positive voltage to the EN0 and EN1, the transistors Q1, XQ1, Q2, and XQ2 are turned on and the ferroelectric capacitors CF0, XCF0, CF1 and XCF1 are connected to the storage nodes N0 or XN0. Also, a negative voltage is applied to the EQ0 and EQ1 and the transistors Q3, XQ3, Q4 and XQ4 are turned off. Next, when a positive voltage pulse is applied to the plate line PL0, potentials distributed to the ferroelectric capacitors CF0 and CF1 are generated at N0 and potentials distributed to the XCF0 and XCF1 are generated at XN0. The capacitance value of the ferroelectric changes depending on a polarization direction. In this case, the capacitance value of the upward polarization is smaller than that of the downward polarization. Accordingly, among the ferroelectric capacitors CF0 and XCF0 in which complementary polarization directions are stored, the storage node connected to the capacitor with upward polarization becomes lower potential than the storage node connected to the capacitor with downward polarization. In the case where the polarization directions stored in the data storage ferroelectric capacitors CF0 and XCF0 are respectively upward and downward, the storage nodes N0 and XN0 respectively become a low potential and high potential (corresponding to the dashed line and solid line in FIG. 22). In the case where the polarization directions stored in the CF0 and XCF0 are respectively downward and upward, the N0 and XN0 respectively become the high potential and the low potential. In the case where strontium bismuth tantalate (SRBi2Ta209) with a film thickness of 100 nm is used for a ferroelectric material, a potential difference to be generated at the storage nodes herein is 650 mV. Next, the power is applied to the inverters INV0 and INV1 so that the potential difference of the storage nodes is amplified to the level of the power voltage VDD level. This is an operation by which the N0 and XN0 show full amplitude at a timing t0 in FIG. 22. By the data reading operation from the ferroelectrics, the data is restored to the latch circuit as potentials complementary to the storage nodes N0 and XN0 of the latch circuit. In the case where the amplitude of the storage node potential by the amplifying operation of the latch circuit sufficiently exceeds the coercive voltage of the ferroelectric, a rewriting operation of the polarization which switched by the reading is unnecessary.

In the present embodiment of the present invention, the load ferroelectric capacitors CF1 and XCF1 are previously polled in a direction where the polarization is not reversed by the data reading operation. Consequently, the imprint resistance is increased. Hereafter, the reason is explained with reference to diagrams.

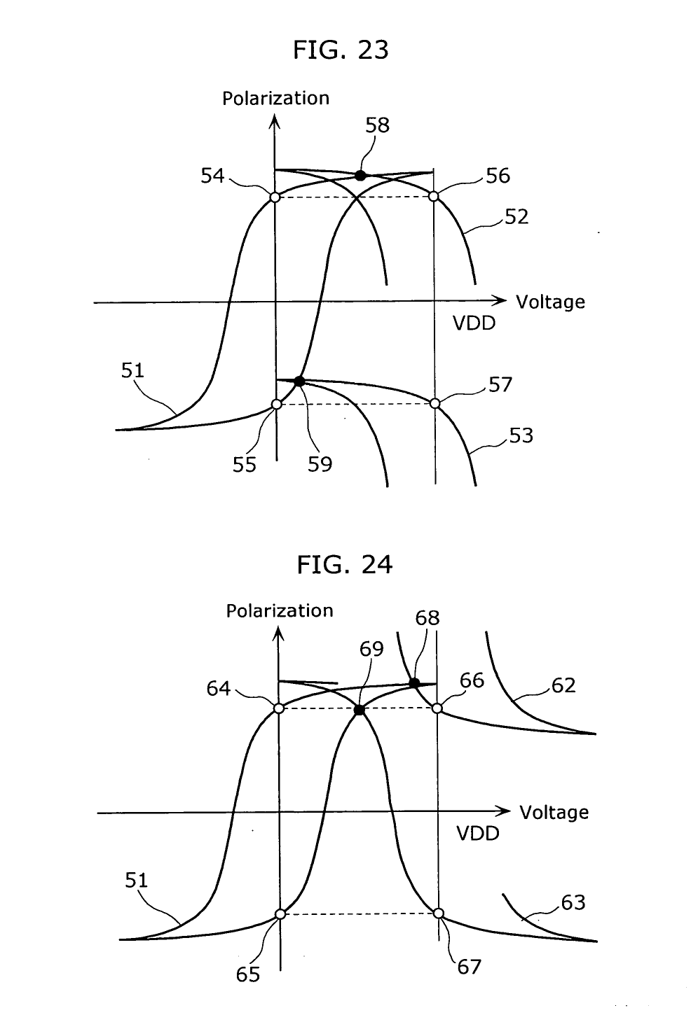

FIGS. 23 and 24 are diagrams showing potentials generated at a common node, that is, the storage nodes of the latch, when a reading voltage is applied to the serial-connected ferroelectric capacitors for data storage and load. The diagrams respectively show a case where the load ferroelectric capacitors are polled in an upward direction and in a downward direction. A polarization hysteresis 51 that is a voltage unipolarization characteristic of the ferroelectric is plotted as ordinary for the data storage ferroelectric capacitors, and the load ferroelectric capacitors hysteresis 52, 53, 62 and 63 are plotted by reversing to the polarization axis and shifting the amount of the applied voltage VDD. Further, the hysteresis of the load ferroelectric capacitors have, on the polarization axis, an offset that is the polarization to be read, that is initial polarization values 54, 55, 64 and 65 stored in the data storage ferroelectric capacitors. The offsets are corresponding to the initial polarization values 56, 57, 66 and 67. Accordingly, for one data storage ferroelectric capacitor hysteresis 51, two load ferroelectric capacitor hysteresises 52 and 53, and 62 and 63 are drown depending on the stored polarization, and the potentials generated at the common nodes are obtained from their points of intersection 58, 59, 68, and 69. The common node potential differences (potential differences between 58 and 59, and between 68 and 69) read from sets of the up-down polarizations: a set of 54 and 55; and a set of 64 and 65 of the load ferroelectric capacitors are equal for the case where the load ferroelectric is polled in upward polarizations 56 and 57, and for the case where the load ferroelectric capacitors are polled in downward polarizations 66 and 67. The common node potential difference is 650 mV.

However, the ferroelectric having symmetrical hysteresis is imprinted in high-temperature and the hysteresis is shifted. For example, if the ferroelectric in which the upward polarization (correspond to positive polarization 6 in FIG. 23) is left for 100 hours at 125° C., the hysteresis shifted −150 mV toward a direction of the voltage axis. On the contrary, in the case of the downward polarization (correspond to negative polarization 6 in FIG. 23), the hysteresis shifts +150 mV. While the shifting of the hysteresis hardly influences an operation of the upward polarization (positive polarization), it gives an offset to an operation point of the downward polarization (negative polarization).

In the case where the hysteresis is shifted ±150 mV due to the imprint, a common node potential difference for the worst case is estimated. In the case where the load ferroelectric capacitor shown in FIG. 23 is polled in upward, the operation point 58 whose two ferroelectric hysteresises are upward polarizations (positive polarization) 54 and 56 does not change by the imprint, the operation point 59 of the downward polarization (negative polarization) 55 and the upward polarization (positive polarization) 57 is shifted +150 mV and the common node potential difference becomes 500 mV. On the other hand, in the case where the load ferroelectric capacitor shown in FIG. 24 is polled in downward direction, the operation point 68 whose two ferroelectric hysteresises are the upward polarization (positive polarization) 64 and the downward polarization (negative polarization) 56 is shifted −150 mV, and the operation point 69 of the downward polarization (negative polarization) 65 and the downward polarization (positive polarization) 67 is shifted +300 mV and the common node potential difference becomes 200 mV. As described in the above, as the result of polling the load ferroelectric capacitors CF1 and XCF1 by a reading operation in upward in which the polarization is not reversed, the initial common node potential difference 650 mV is reduced to 500 mV by the imprint. This is 2.5 times of 200 mV for the downward polling so that stable operation is possible.

### Third Embodiment

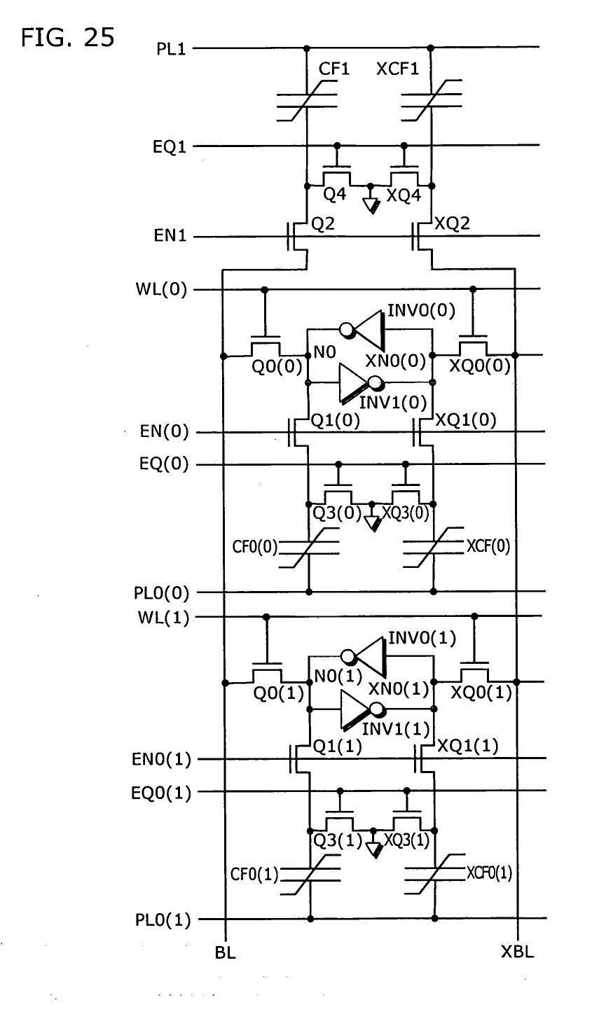

FIG. 25 shows a ferroelectric built-in latch circuit diagram according to a third embodiment of the present invention. In the present embodiment, there are two memory cells composed of a latch circuit and data storage ferroelectric capacitors and a load cell including load ferroelectric capacitors is shared. In FIG. 25, an element to which a number (0) is attached forms a first memory cell and an element to which a number (1) is attached forms a second memory cell. The latch circuit is formed by connecting two inverters INV0 (0, 1) and INV1 (0, 1) in cross couple. In the latch circuit, data is written in and read from the bit lines BL and XBL by the access transistors Q0 (0, 1) and XQ0 (0, 1) whose gates are controlled by the word line WL (0, 1). Two data storage ferroelectric capacitors CF0 (0, 1) and XCF0 (0, 1) are respectively connected to the two storage nodes N0 (0, 1) and XN0 (0, 1) of the latch circuit via the transistors Q1 (0, 1) and XQ1 (0, 1) whose gates are controlled by the control line EN0 (0, 1). These connection nodes are available for grounding by the transistors Q3 (0, 1) and XQ3 (0, 1) whose gates are controlled by the control line EQ0 (0, 1). One side of electrodes of the CF0 (0, 1) and XCF0 (0, 1) is connected to the plate line PL0. The two load ferroelectric capacitors CF1 (0, 1) and XCF1 (0, 1) are connected to the load cell via the transistors Q2 (0, 1) and XQ2 (0, 1) whose gates are controlled by the control line EN1 (0, 1). These connection nodes are available for grounding by the transistors Q4 (0, 1) and XQ4 (0, 1) whose gates are controlled by the control line EQ1 (0, 1). The other side of the electrodes of the CF1 (0, 1) and XCF1 (0, 1) are connected to the plate line PL1.

Such ferroelectric built-in latch circuit holds EN0 (0, 1) and EN1 and PL0 (0, 1) and PL1 at low potential in an ordinary operational state, the EQ0 (0, 1) and PL1 at high potential, and operates as a latch circuit which reads and writes complementary data to the BL and the XBL.

The ferroelectric built-in latch circuit in the present embodiment executes a process in which the polarization directions of the load ferroelectric capacitors CF1 and XCF1 are turned to be upward (it is a direction in which the polarization is not reversed in data reading process from the data storage ferroelectric capacitors). The polling process is performed before the shipping of the ferroelectric built-in latch circuit. Since the polarization is not reversed by the reading process, it is not necessary to perform polling process after the shipping. However, it may be performed before the reading operation or before turning off the power when necessary since it is assumed the case where the polarization is lowered because of a long-term storage. In the polling process, by applying a positive voltage to the EN1, the transistors Q2 and XQ2 are turned on and the load ferroelectric capacitors CF1 and XCF1 are respectively connected to the bit lines BL and XBL. Also, a negative voltage is applied to the EQ1 so as to turn off the transistors Q4 and XQ4. Next, while keeping the plate line PL1 at the low potential, a positive voltage pulse is applied to the bit lines BL and XBL. Herein, by applying the voltage to the CF1 and XCF1 enough to reverse the polarization of the ferroelectric, the polarization direction becomes upward.

The ferroelectric built-in latch circuit in an ordinary state operates as two latch circuits selected by the word lines WL (0, 1). However, when the power is turned off, the complementary potential states of the storage nodes N0 (0, 1) and XN0 (0, 1) of the latch circuits are stored as polarization directions of the data storage ferroelectric capacitors CF0 (0, 1) and XCF0 (0, 1). The data writing operation into the ferroelectrics is performed on two memory cells at the same time. First, by applying a positive voltage to the EN0 (0, 1), the transistors Q1 (0, 1) and XQ1 (0, 1) are turned on, and the data storage ferroelectric capacitors CF0 (0, 1) and XCF0 (0, 1) are respectively connected to the storage nodes N0 (0, 1) and XN0 (0, 1) of the latch circuits. Also, a negative voltage is applied to the EQ0 (0, 1) so as to turn off the transistors Q3 (0, 1) and XQ3 (0, 1). Herein, the polarizations of the data storage ferroelectric capacitors connected to the storage nodes held at the high potentials become downward in FIG. 25. Then, a positive voltage pulse is applied to the plate line PL0 (0, 1) so as to turn the polarizations of the data storage ferroelectric capacitors connected to the storage nodes held at the low potential to upward. After the data writing operation into the ferroelectrics is completed, the power is turned off.

At the time when the ferroelectric built-in latch circuit is started, the data stored as polarization directions of data storage ferroelectric capacitors CF0 (0, 1) and XCF0 (0, 1) of two memory cells are sequentially read out and restored to the latch circuit as complementary potentials of the storage nodes N0 (0, 1) and XN0 (0, 1) of the latch circuits. In the operation of reading data from the ferroelectrics of the first memory cell, first, in a state where the power (not shown in FIG. 25) of the inverters INV0 (0) and INV1(0) is turned off, a positive voltage is applied to the WL (0), EN0 (0) and EN1 (0) so as to turn on the transistors Q0 (0), XQ0 (0), Q1 (0), XQ1 (0), Q2 and XQ2, and connect the ferroelectric capacitors CF0 (0), XCF0 (0), CF1 and XCF1 to the storage nodes N0 (0) or XN0 (0). Also, a negative voltage pulse is applied to the EQ0 (0) and EQ1 so as to turn off the transistors Q3 (0), XQ3 (0), Q4 and XQ4. Next, when a positive voltage pulse is applied to the plate line PL0 (0), potentials that are divided into the ferroelectric capacitors CF0 (0) and CF1 are generated at the N0 (0), and potentials that are divided into the ferroelectric capacitors XCF0 (0) and XCF1 are generated at XN0 (0). In the case where the potential directions stored in the data storage ferroelectric capacitors CF0 (O) and XCF0 (0) are respectively upward and downward, the storage nodes N0 (0) and XN0 (0) are respectively turned to low potential and high potential. In the case where the potential directions stored in the data storage ferroelectric capacitors are respectively downward and upward, the N0 (0) and XN0 (0) respectively turned to high and low potentials. Next, by supplying power to the inverters INV0 (0) and INV1 (0), the potential difference of the storage nodes is amplified up to the power voltage VDD level. Through the operation of reading data from the ferroelectrics, the data in the first memory cell is restored to the latch circuit as complementary potentials of the storage nodes N0 (0) and XN0 (0) of the latch circuit. Following that, similar reading operation is performed on the second memory cell. Note that, an operation of supplying power to the inverters INV0 (0, 1) and INV1 (0, 1) and amplifying the storage node potential full can be performed commonly to the memory cells. Consequently, the start-up time can be shortened.

### Fourth Embodiment

The ferroelectric built-in latch circuit according to the fourth embodiment of the present invention is similar to that of the second embodiment. In an ordinary operation state, it operates as a latch circuit in which the EN0 and EN1 and the PL0 and PL1 are set to low potentials and the EQ0 and EQ1 are set to high potentials, controlled by switching on and off the WL, and data complementary to the BL and the XBL are transmitted.

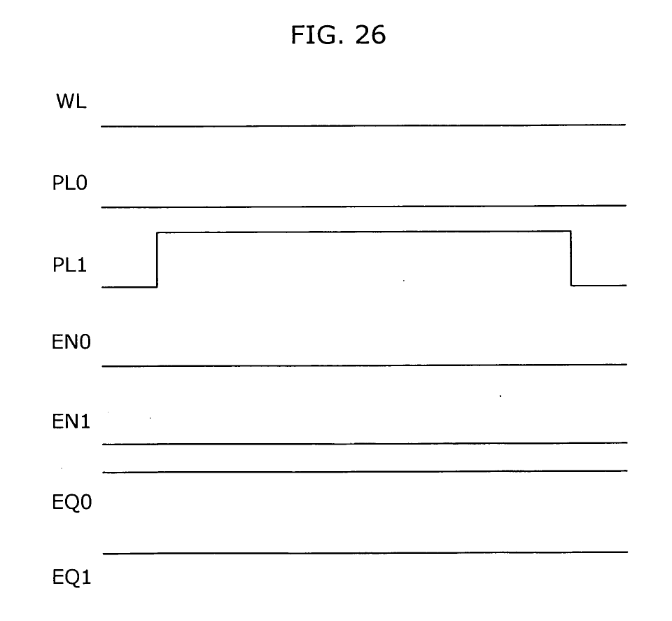

A driving unit 10 in the present embodiment performs polling process of applying driving waveforms shown in FIG. 26 in order to have the polarization directions of the load ferroelectric capacitors CF1 and XCF1 downward. The polling process is performed before shipping the ferroelectric built-in latch circuit and after writing data from the latch circuit that is described later into the data storage ferroelectric capacitors. In the polling process, a positive pulse is applied to the plate line PL1 as shown in FIG. 26. Herein, by applying the voltage enough to reverse the polarizations of the ferroelectrics to the CF1 and XCF1, the polarization directions become downward.

The ferroelectric built-in latch circuit in an ordinary state operates as a latch circuit. However, when the power is turned off, the states of potentials complementary to the storage nodes N0 and XN0 of the latch circuit are stored as polarization directions of the data storage ferroelectric capacitors CF0 and XCF0. The operation of writing data into the ferroelectrics is realized by applying the driving waveforms shown in FIG. 21 as similar in the second embodiment. First, by applying a positive voltage to the EN0, the transistors Q1 and XQ1 are turned on and the data storage ferroelectric capacitors CF0 and XCF0 are respectively connected to the storage nodes N0 and XN0 of the latch circuit. Also, a negative voltage is applied to the EQ0 so as to turn off the transistors Q3 and XQ3. Herein, the polarization of the data storage ferroelectric capacitors connected to the storage nodes which are high potentials become downward. Next, by applying a positive voltage pulse to the plate line PL0 so as to make the polarization of the data storage ferroelectric capacitors connected to the storage nodes which are low potentials become upward. After the operation of writing data into the ferroelectrics, the power is turned off.

Summarizing the polarization state, the load ferroelectric capacitors CF1 and XCF1 have downward polarization by the polling processing, the data storage ferroelectric capacitors CF0 and XCF0 respectively have the following polarization directions: upward and downward when the storage nodes N0 and XN0 are respectively low potential and high potential by the data writing processing; and downward and upward when the storage nodes N0 and XN0 are respectively high potential and low potential.

At the time when the ferroelectric built-in latch circuit is started, the data stored as polarization directions of the data storage ferroelectric capacitors CF0 and XCF0 are restored to the latch circuit as potentials complementary to the storage nodes N0 and XN0 of the latch circuit. The operation of reading data from the ferroelectrics can be realized by applying the driving waveforms shown in FIG. 22 as similar in the second embodiment. First, in a state where the power of the inverters INV0 and INV1 is turned off (not shown in FIG. 19), by applying a positive voltage to the EN0 and EN1, the transistors Q1, XQ1, Q2 and XQ2 are turned on and the ferroelectric capacitors CF0, XCF0, CF1 and XCF1 are connected to the storage nodes N0 and XN0. Also, a negative voltage is applied to the EQ0 and EQ1 so as to turn off the transistors Q3, XQ3, Q4 and XQ4. Next, when a positive voltage pulse is applied to the plate line PL0, potentials that are distributed into the ferroelectric capacities CF0 and CF1 are generated at the N0, and potentials that are distributed into the CF0 and XCF1 are generated at XN0. Herein, the upward polarization has smaller capacitance value than the downward polarization. Accordingly, among the ferroelectric capacitors CF0 and XCF0 in which complementary polarization directions are stored, the storage node connected to the capacitor with upward polarization has smaller potential than the stprage node connected to the capacitor with downward polarization. In the case where the polarization directions stored in the data storage ferroelectric capacitors CF0 and XCF0 are respectively upward and downward, the storage nodes N0 and XN0 are respectively the low potential and the high potential (corresponding to a dashed line and a solid line in FIG. 22). In the case where the polarization directions stored in CF0 and XCF0 are respectively downward and upward, the N0 and XN0 are respectively the high potential and the low potential. Next, by supplying the power to the inverters INV0 and INV1, the potential difference of the storage nodes is amplified up to the power voltage VDD level. Through the operation of reading data from the ferroelectrics, the data are restored to the latch circuit as potentials complementary to the storage nodes N0 and XN0 of the latch circuit.

In the embodiment of the present invention, a polling process is performed again after the operation of writing data before the power is turned off since the polarizations of the load ferroelectric capacitors CF1 and XCF1 are reversed by the operation of reading data. Consequently, even if the load ferroelectrics are imprinted in the case of being left in a high-temperature while the power is turned off, the shifting directions of two load ferroelectric hysteresises are the same so that the storage node potential difference can be controlled at 500 mV as estimated in the second embodiment.

### Fifth Embodiment

In the present embodiment, it is explained about an applied example of the ferroelectric built-in latch circuit shown in first to fourth embodiments.

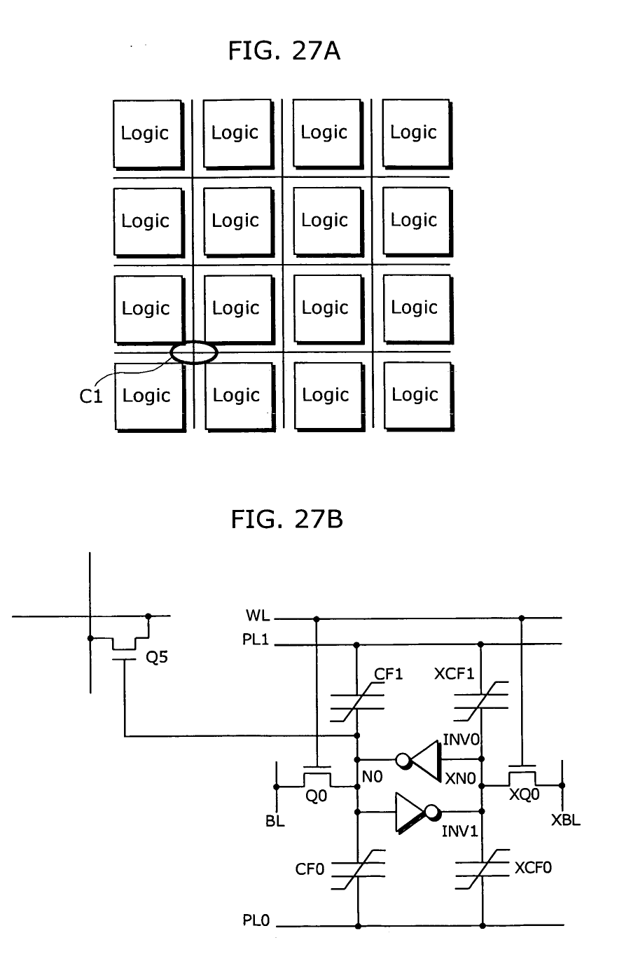

FIG. 27A is a diagram showing a schematic structure of a programmable logic device having ferroelectric built-in latch circuits in the present embodiment. The programmable logic device has a plurality of unit logic circuits (shown as Logic in FIG. 27A) and wiring (vertical lines and horizontal lines in FIG. 27A) for mutually connecting the unit logic circuits. Each of the unit logic circuit is a programmable logic arithmetic circuit. For example, it is a Look-Up Table (LUT) with four inputs and one output, and the like. The wiring includes a plurality of wires running vertically and horizontally between the unit logic circuits and a plurality of connection circuits for connecting intersections of the vertical and horizontal wires.

FIG. 27B is a diagram showing a detail of the connection circuit. As shown in FIG. 27B, each point of intersections of wires is connected to a connection switch transistor Q5 and a ferroelectric built-in latch circuit. The connection switch transistor Q5 switches on or off depending on the configuration data of the storage node N0 of the ferroelectric built-in latch circuit. Consequently, the arbitral input and output of the unit logic circuit can be connected.

As the ferroelectric built-in latch circuit, the ferroelectric built-in latch circuit shown in FIG. 19 and FIG. 26 can be used. Also, the ferroelectric built-in latch circuit can be corresponded to the plurality of points of intersections.

Note that, in the first to fifth embodiments, the inverters connected in cross couple are used in the latch circuit. However, not to mention that it is not limited to the inverters.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be constructed as being included therein.

1. A semiconductor memory device comprising:
a volatile latch circuit which holds data;
a nonvolatile ferroelectric capacitor circuit which holds data; and
a switch circuit which connects and disconnects between said latch circuit and said ferroelectric capacitor circuit.

2. The semiconductor memory device according to claim 1,
wherein said switch circuit connects between said latch circuit and said ferroelectric capacitor circuit only when data is transferred between said latch circuit and said ferroelectric capacitor circuit.

3. The semiconductor memory device according to claim 1, further comprising
a logic circuit whose configuration is changeable in accordance with the data held in said latch circuit.

4. The semiconductor memory device according to claim 3,
wherein said ferroelectric capacitor circuit includes:
a first circuit having a nonvolatile ferroelectric element which holds data; and
a second circuit having a nonvolatile ferroelectric element which holds data, and
said switch circuit selects one of the first circuit and the second circuit, and connects between the selected circuit and said latch circuit only when data is transferred between said latch circuit and said ferroelectric capacitor circuit.

5. The semiconductor memory device according to claim 4,
wherein said logic circuit is one of i) a switch transistor which is turned on depending on the data held in said latch circuit, ii) a buffer circuit whose output is controlled depending on the data held in said latch circuit, and iii) a selection circuit whose selection is controlled depending on the data held in said latch circuit.

6. The semiconductor memory device according to claim 4, comprising:
a table circuit which is formed of unit circuits,
wherein one of the unit circuits includes said latch circuit, said ferroelectric capacitor circuit and said switch circuit and each of the other unit circuits has a same structure as the one unit circuit, and
said logic circuit is a selection circuit which selects one of the unit circuits.

7. The semiconductor memory device according to claim 4, comprising
circuit blocks for processing data,
wherein one of said circuit blocks includes said latch circuit, said ferroelectric capacitor circuit, said switch circuit and said logic circuit, and each of the other circuit blocks has a same structure as said one circuit block.

8. The semiconductor memory device according to claim 7, further comprising
a control unit operable to control reconfiguration of a circuit configuration for each circuit block.

9. The semiconductor memory device according to claim 8,
wherein said circuit blocks include a first circuit block and a second circuit block, and
said control unit is operable to reconfigure a circuit configuration of the second circuit block while data is processed in the first circuit block.

10. The semiconductor memory device according to claim 8,
wherein said control unit is operable to reconfigure a circuit configuration of said circuit blocks, each of which is separately reconfigured.

11. The semiconductor memory device according to claim 8,
wherein said circuit blocks include circuit block groups corresponding to respective stages of a pipeline processing, and
said control unit is operable to reconfigure a circuit configuration of each circuit block groups in order of the stages.

12. The semiconductor memory device according to claim 11,
wherein said control unit is operable to make the circuit block groups start processing of the respective stages in order of the reconfiguration.

13. The semiconductor memory device according to claim 11,
wherein said control unit is operable to sequentially reconfigure said circuit blocks starting from a circuit block on which processing of a stage is completed.

14. The semiconductor memory device according to claim 8,
wherein the data processing includes repetitive processing, and
said control unit is operable to reconfigure one of said circuit blocks so as to feedback to said circuit block with a processing result before a first iteration, and to reconfigure said circuit block so as not to feedback to said circuit block just before a last iteration.

15. The semiconductor memory device according to claim 2,
wherein data is transferred at least with two clocks from said ferroelectric capacitor circuit to said latch circuit.

16. The semiconductor memory device according to claim 15, comprising
a load capacitor circuit which includes a ferroelectric capacitor that is connected to said ferroelectric capacitor circuit as a load capacitor.

17. The semiconductor memory device according to claim 16,
wherein a polarization of said load capacitor circuit is in a direction which is not reversed in a process of reading data from said ferroelectric capacitor circuit.

18. The semiconductor memory device according to claim 17, comprising
a driving unit operable to output a driving signal for aligning the polarization of said load capacitor circuit in one direction.

19. The semiconductor memory device according to claim 16,
wherein said driving unit is operable to aligning the polarization of said load capacitor circuit in one direction which is not reversed by the reading operation.

20. The semiconductor memory device according to claim 16, comprising
memory cells, one of which includes said latch circuit and said ferroelectric capacitor circuit and each of the other memory cells has a same structure as said one memory cell,
wherein said load capacitor circuit and said memory cells are connected to each other on a one-to-many basis.

21. The semiconductor memory device according to claim 16, comprising
memory cells, one of which includes said latch circuit and said ferroelectric capacitor circuit and each of the other memory cells has a same configuration as said one memory cell,
wherein said load capacitor circuit and said memory cell are connected to each other on a one-to-one basis.

22. The semiconductor memory device according to claim 16,
wherein said ferroelectric capacitor circuit includes one pair of ferroelectric capacitor elements, and
said load capacitor circuit includes one pair of ferroelectric capacitor elements.

23. A semiconductor memory device comprising:
a volatile latch circuit which holds data;
a nonvolatile ferroelectric capacitor circuit which holds data written and read with said latch circuit; and
a load capacitor circuit which is a ferroelectric capacitor connected to said ferroelectric capacitor as a load capacitor.

24. The semiconductor memory device according to claim 23,
wherein a polarization of said load capacitor circuit is in a direction which is not reversed by a process of reading data from said ferroelectric capacitor circuit.

25. The semiconductor memory device according to claim 24, comprising
a driving unit operable to output a driving signal for aligning the polarization of the load capacitor circuit in one direction.

26. The semiconductor memory device according to claim 25,
wherein said driving unit is operable to align the polarization of the load capacitor circuit in one direction which is not reversed by a reading operation.

27. The semiconductor memory device according to claim 24, comprising
memory cells, one of which includes said latch circuit and said ferroelectric capacitor circuit and each of the other memory cells has a same structure as said one memory cell,
wherein said load capacitor circuit and said memory cells are connected to each other on a one-to-many basis.

28. The semiconductor memory device according to claim 24, comprising
memory cells, one of which includes said latch circuit and said ferroelectric capacitor circuit and each of the other memory cells has a same configuration as said one memory cell,
wherein said load capacitor circuit and said memory cell are connected to each other on a one-to-one basis.

29. The semiconductor memory device according to claim 24,
wherein said ferroelectric capacitor circuit includes a pair of ferroelectric capacitor elements, and
said load capacitor circuit includes a pair of ferroelectric capacitor elements.
